(19) United States
(12) Patent Application Publication
(10) Pub. No.: US 2015/0274938 A1
(43) Pub. Date: Oct. 1, 2015

(54) Curable Silicone Composition, And Semiconductor Sealing Material And Optical Semiconductor Device Using The Same

(71) Applicant: DOW CORNING TORAY CO., LTD., Tokyo (JP)

(72) Inventors: Tadashi Okawa, Ichihara-shi (JP); Kazuhiko Kojima, Ichihara-shi (JP); Tomohiro Iimura, Ichihara-shi (JP); Haruhiko Furukawa, Ichihara-shi (JP)

(21) Appl. No.: 14/428,791

(22) PCT Filed: Sep. 20, 2013
(86) PCT No.: PCT/JP2013/076887

§ 371 Date: Mar. 24, 2015

(30) Foreign Application Priority Data
Sep. 21, 2012 (JP) 2012-208700
Jul. 4, 2013 (JP) 2013-141090

(51) Int. Cl. C08K 9/06; H01L 33/56; C08K 9/02

(52) U.S. Cl. CPC C08K 9/06; C08K 9/02; H01L 33/56; H01L 2933/005

(57) ABSTRACT

A hydrosilylation reaction curable curable silicone composition comprising barium titanate microparticles or barium titanate microparticles having a surface which is partially or fully covered by a silica layer with a cumulant average particle size of at most 200 nm, wherein a refractive index after curing is at least 1.55, preferably a curable silicone composition in which the barium titanate microparticles are barium titanate microparticles surface-treated by an organosilicon compound having a silicon atom-containing hydrolyzable group etc. bonded to silicon atoms directly or via a functional group with a valency of (n+1) (n is a number equal to 1 or greater) and having at least one structure in the molecule in which the silicon atoms are bonded to other siloxane units.

### TECHNICAL FIELD

Priorities are claimed on Japanese Patent Application No. 2012-208700 and No. 2013-141090, filed on Sep. 21, 2012 and Jul. 4, 2013, the content of which are incorporated herein by reference.

The present invention relates to a curable silicone composition containing barium titanate microparticles or barium titanate microparticles having a surface which is partially or entirely covered by a silica layer, the curable silicone composition yielding a cured product with excellent transparency, high refringency, and thermal stability, and a semiconductor sealing material and optical semiconductor device using the same.

### BACKGROUND ART

Silicone resins are widely used in the field of electronic materials requiring high durability due to their excellent heat resistance and light resistance in comparison to materials made of organic polymers. In particular, in applications for optical materials such as light-emitting diodes (LEDs), silicone resins are widely used in high-brightness optical semiconductor sealing materials, solar cell films requiring durability due to stringent usage environments, and lenses with stringent usage conditions. On the other hand, typical silicone resins primarily consisting of methylsiloxane units have a refractive index of around 1.4, but there is a demand for improvements in light-extraction efficiency from the perspective of energy conservation in high-brightness optical semiconductor sealing materials, and the improvement of refractive index has become an issue.

As a method for improving the refractive index of a curable composition consisting of a silicone resin, a method is being investigated to adjust the refractive index of a resin by dispersing metal oxides having a high refractive index such as titanium oxide or zirconium oxide into the resin. Of these metal oxides having a high refractive index, metal oxide microparticles having a particle size so small that light scattering can be ignored are useful for obtaining a silicone resin with a high refractive index.

On the other hand, these metal oxides having a high refractive index are subject to aggregation in the untreated state due to the high hydrophilicity of the surface, which may cause poor dispersion into a hydrophobic silicone resin. Therefore, several treatment methods have been proposed in order to solve these problems (see Patent Documents 1 to 5). However, when metal oxide microparticles such as titanium oxide or zirconium oxide are treated using these methods, although the dispersion stability of the metal oxide microparticles in the silicone resin can be improved to a certain degree, the thermal stability of the resulting cured product is lost, which is problematic in that it leads to degradation such as the yellowing of the cured product. On the other hand, it is difficult to add large quantities of metal oxide microparticles in the untreated state to a hydrophobic silicone resin, and it is difficult to realize a high refractive index—in particular, a high refractive index of 1.55 or higher.

In addition, the use of a dimethylsilicone-based filler treatment agent having a silicon-bonded alkoxysilyl ethyl group as a side chain is proposed in Patent Document 2 (Japanese Unexamined Patent Application Publication No. 2010-241935), but since the refractive index of the dimethylsilicone portion is low, it is unsuitable for obtaining a composition with a high refractive index.

Further, in Patent Document 4 (Japanese Unexamined Patent Application Publication No. 2010-144137), a silicone resin composition is proposed, the silicone resin composition being obtained by performing a polymerization reaction on a silicone derivative having an alkoxysilyl group at the molecular terminal or a side chain and metal oxide microparticles having reactive functional groups on the microparticle surface, wherein the alkoxysiyl group is a silyl group having an alkoxy group and an aromatic group as functional groups directly bonded to silicon. However, since the alkoxy group and the aromatic group are present on the same silicon atom, the reactivity of this alkoxysilyl group with the reactive functional groups on the surface of the microparticles is low, which leads to the problem that sufficient modification effects are difficult to achieve.

As described above, there has been no known silicone resin containing metal oxide microparticles with a high refractive index of at least 1.55, wherein the metal microparticles can be finely and stably added in large quantities and the thermal stability of the silicone resin is excellent after curing.

Further, a known surface treatment agent for metal oxide microparticles primarily consists of a silane or a dimethyl silicone portion with a low refractive index as siloxane moieties, and there is no mention or suggestion of a surface treatment agent or the concept of a surface treatment agent which has excellent surface treatment performance and itself has a very high refractive index. Further, the documents related to these known surface treatment agents make no mention or suggestion of a surface treatment agent having a high refractive index and having functional groups that are reactive with silicone resins.

### PRIOR ART DOCUMENTS

### Patent Documents

Patent Document 1: Japanese Unexamined Patent Application Publication No. 2011-026444
Patent Document 2: Japanese Unexamined Patent Application Publication No. 2010-241935
Patent Document 3: Japanese Unexamined Patent Application Publication No. 2010-195646
Patent Document 4: Japanese Unexamined Patent Application Publication No. 2010-144137
Patent Document 5: WO2010/026992

### SUMMARY OF INVENTION

### Technical Problem

An object of the present invention is to provide a curable silicone composition having a refractive index of at least 1.55 after curing and having excellent transparency and thermal stability, and a semiconductor sealing material and an optical semiconductor device using the same.

### Solution to Problem

As a result of intensive investigation aimed at achieving the above objects, the present inventors arrived at the present invention. That is, the object of the present invention is achieved by a curable silicone composition containing (A) barium titanate microparticles or barium titanate microparticles having a surface which is partially or entirely covered by a silica layer with a cumulant average particle size of at most 200 nm, wherein a refractive index after curing is at least 1.55, preferably a curable silicone composition in which the barium titanate microparticles or barium titanate microparticles having a surface which is partially or entirely covered by a silica layer are barium titanate microparticles or barium titanate microparticles having a surface which is partially or entirely covered by a silica layer surface-treated by (B) an organosilicon compound having a functional group selected from a highly polar functional group, a hydroxyl group-containing group, a silicon atom-containing hydrolyzable group, or metal salt derivatives thereof bonded to silicon atoms directly or via a functional group with a valency of (n+1) (n is a number equal to 1 or greater) and having at least one structure in the molecule in which the silicon atoms are bonded to other siloxane units, the curable silicone composition being hydrosilylation reaction curable. Here, the organosilicon compound serving as the component (B) has a refractive index of at least 1.45 at 25° C. and further has hydrosilylation-reactive functional groups in the molecule.

In addition, the object of the present invention is preferably achieved by a hydrosilylation reaction curable silicone composition containing an organopolysiloxane represented by the average unit formula:

(R²¹₃SiO_{1/2})ₐ(R²¹₂SiO_{2/2})_{b}(R²²SiO_{3/2})_{c}(SiO_{4/2})_{d}

(wherein, the R²¹ moieties are alkyl groups, alkenyl groups, phenyl groups, or hydrogen atoms; the R²² moieties are groups represented by R¹, condensed polyaromatic groups, or groups including a condensed polyaromatic group, provided that at least one of the R²¹ or R²² moieties in the molecule is an alkenyl group or hydrogen atom and at least one R² moiety in the molecule is a condensed polyaromatic group or a group including a condensed polyaromatic group; and a, b, c, and d are numbers satisfying the formulae: 0.01≦a≦0.8, 0≦b≦0.5, 0.2≦c≦0.9, 0≦d<0.2, and a+b+c+d=1;

Further, the object of the present invention is preferably achieved by a cured product of the curable silicone composition and an optical semiconductor device formed by covering or sealing an optical semiconductor element with the cured product.

Specifically, the object of the present invention is achieved by:

“[1] A curable silicone composition comprising: (A) barium titanate microparticles or barium titanate microparticles having a surface which is partially or entirely covered by a silica layer with a cumulant average particle size of at most 200 nm, a refractive index after curing being at least 1.55.
[2] The curable silicone composition according to [1], further comprising: (B) an organosilicon compound having a functional group selected from a highly polar functional group, a hydroxyl group-containing group, a silicon atom-containing hydrolyzable group, or metal salt derivatives thereof bonded to silicon atoms directly or via a functional group with a valency of (n+1) (n is a number equal to 1 or greater) and
having at least one structure in the molecule in which the silicon atoms are bonded to any siloxane unit represented by R¹₃SiO_{1/2}, R¹₂SiO_{2/2}, R¹SiO_{3/2}, and SiO_{4/2} (wherein R¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1)).
[3] The curable silicone composition according to [2], wherein the component (A) comprises barium titanate microparticles or barium titanate microparticles having a surface which is partially or entirely covered by a silica layer surface-treated by the component (B), the curable silicone composition being hydrosilylation reaction curable.
[4] The curable silicone composition according to [2] or [3], comprising: (A) barium titanate microparticles or barium titanate microparticles having a surface which is partially or entirely covered by a silica layer with a cumulant average particle size of at most 200 nm;
(B) an organosilicon compound having a functional group selected from a highly polar functional group, a hydroxyl group-containing group, a silicon atom-containing hydrolyzable group, or metal salt derivatives thereof bonded to silicon atoms directly or via a functional group with a valency of (n+1) (n is a number equal to 1 or greater), and
having at least one structure in the molecule in which the silicon atoms are bonded to any siloxane unit represented by R³¹₃SiO_{1/2}, R³¹₂SiO_{2/2}, R³¹SiO_{3/2}, and SiO_{4/2} (wherein R³¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1));
(C) an organopolysiloxane having at least two alkenyl groups in each molecule;
(D) an organopolysiloxane having at least two silicon-bonded hydrogen atoms in each molecule; and
(E) a hydrosilylation reaction catalyst.
[5] The curable silicone composition according to [4], wherein part or all of the component (C) or the component (D) is an organopolysiloxane represented by the average unit formula:

(R²¹₃SiO_{1/2})ₐ(R²¹₂SiO_{2/2})_{b}(R²²SiO_{3/2})_{c}(SiO_{4/2})_{d}

(wherein the R²¹ moieties are alkyl groups, alkenyl groups, phenyl groups, or hydrogen atoms; the R²² moieties are groups represented by R²¹, condensed polyaromatic groups, or groups including a condensed polyaromatic group, provided that at least two of the R²¹ or R²² moieties in the molecule are alkenyl groups or hydrogen atoms and at least one R²² moiety in the molecule is a condensed polyaromatic group or a group including a condensed polyaromatic group; and a, b, c, and d are numbers satisfying the formulae: 0.01≦a≦0.8, 0≦b≦0.5, 0.2≦c≦0.9, 0≦d<0.2, and a+b+c+d=1).
[6] The curable silicone composition according to any one of [2] to [5], wherein the component (B) is an organosilicon compound having: an alkenyl group or a silicon-bonded hydrogen atom in the molecule; and
a silicon-bonded hydrolyzable group or hydroxyl group bonded to silicon atoms directly or via a functional group with a valency of (n+1) (n is a number equal to 1 or greater).
[7] The curable silicone composition according to any one of [1] to [6], further containing (F) a fluorescent material.
[8] A cured product produced by curing the curable silicone composition described in any one of [1] to [7].
[9] A semiconductor sealing material comprising the curable silicone composition according to one of [1] to [7].
[10] An optical semiconductor device formed by covering or sealing an optical semiconductor element with the curable silicone composition described in any one of [1] to [7].”

### Advantageous Effects of Invention

With the present invention, it is possible to provide a curable silicone composition having a refractive index of at least 1.55 (particularly preferably a refractive index of at least 1.65) after curing and having excellent transparency and thermal stability, and a semiconductor sealing material and an optical semiconductor device using the same.

### BRIEF DESCRIPTION OF THE DRAWING

FIG. 1 is a cross-sectional view of a surface-mounted LED serving as an example of the optical semiconductor device of the present invention.

### DESCRIPTION OF EMBODIMENTS

The curable silicone composition of the present invention is a curable silicone composition containing (A) barium titanate microparticles or barium titanate microparticles having a surface which is partially or entirely covered by a silica layer with a cumulant average particle size of at most 200 nm, wherein a refractive index after curing is at least 1.55. Here, the “cumulant average particle size” is the average particle size of the microparticles calculated from the signal strength when measured with a dynamic light scattering particle size distribution meter using a cumulant method as a correlation calculation method and can be calculated, for example, by a conventional method from the measurement of the particle size distribution according to the dynamic light scattering method. Unless specified otherwise, “particle size” or “average particle size” will hereafter refer to the “cumulant average particle size.” In the experimental examples of the inventions of this application, the cumulant average particle size is measured using a Zeta-potential and Particle Size Analyzer ELSZ-2 (manufactured by Otsuka Electronics Co., Ltd.).

<Component (A)>

Component (A) is one characteristic component of the present invention and consists of barium titanate microparticles or barium titanate microparticles having a surface which is partially or entirely covered by a silica layer with a cumulant average particle size of at most 200 nm. Barium titanate has both a high dielectric constant and refractive index (refractive index: 2.4) and is useful for imparting the silicone cured product with optical and electromagnetic performance. Barium titanate also has the advantage that it has high thermal stability and is unlikely to cause degradation such as yellowing in the cured product over time, even when added together with a surface treatment agent.

Further, since it is possible to reduce photocatalytic activity and thermocatalytic reactivity originating from surface Ti—OH bonds or Ba—OH bonds by covering part or all of the barium titanate surface used in the present invention with a silica layer, it is possible to suitably use barium titanate microparticles having a surface which is partially or entirely covered by a silica layer. In addition, the dispersibility in an organic solvent or silicone can be enhanced by covering the microparticles with a silica layer. Barium titanate microparticles having a surface which is partially or entirely covered by a silica layer have already been proposed in Japanese Unexamined Patent Application Publication No. 2011-246547, but this is barium titanate with a large particle diameter used in white pigments and does not aim to use a silica layer to cover the barium titanate microparticles having a particle size of at most 200 nm that can be used in the present invention. Conventionally known methods can be used to cover the microparticles with a silica layer, such as a method of dispersing barium titanate in an appropriate solvent and then adding a sodium silicate aqueous solution under acidic conditions, a method of adding a silicic acid solution, or a method of hydrolyzing hydrolyzable 4-functional silanes in the presence of a basic catalyst.

When metal oxide microparticles similarly having a high refractive index such as titanium oxide (refractive index: 2.5 to 2.7) or zirconium oxide (refractive index: 1.9 to 2.4) are used, the thermal stability of the resulting cured product is diminished, even if surface treatment is performed with an organosilicon compound as described below, which is not preferable.

The cumulant average particle size of the barium titanate microparticles or the barium titanate microparticles having a surface which is partially or entirely covered by a silica layer is at most 200 nm, particularly preferably from 1 to 175 nm, and more preferably from 1 to 150 nm from the perspective of the transparency of a silicone cured product containing the particles. The shape and particle structure of the powder are not limited whatsoever.

The curable silicone composition contains the component (A) described above, and the refractive index of a resulting cured product after curing is at least 1.55. The refractive index of the cured product is preferably a higher refractive index of at least 1.60, more preferably at least 1.65, and even more preferably from 1.65 to 1.80. The curable silicone composition is preferably cured by a condensation reaction or a hydrosilylation reaction and is particularly preferably cured by a hydrosilylation reaction.

Further, the curable silicone composition of the present invention preferably contains barium titanate microparticles or barium titanate microparticles having a surface which is partially or entirely covered by a silica layer serving as the component (A) and a surface treatment agent, particularly a surface treatment agent consisting of an organosilicon compound. By surface treating the barium titanate microparticles or barium titanate microparticles having a surface which is partially or entirely covered by a silica layer, it is possible to finely and stably disperse the metal oxide microparticles into the curable silicone composition and to stably add larger quantities than in the case of untreated microparticles. As a result, there is the advantage that the optical properties (in particular, high refringence) and electromagnetic properties of the resulting cured product can be dramatically improved.

<Component (B)>

In particular, the curable silicone composition of the present invention preferably contains an organosilicon compound having a specific functional group bonded to silicon atoms in the molecule and having at least one structure in the molecule in which other siloxane units are bonded to the silicon atoms. This organosilicon compound has a site which interacts with the surface of the optical material directly or after hydrolysis and a site which provides characteristics originating from a silicon-based polymer in the same molecule and can therefore dramatically improve the dispersibility of the barium titanate microparticles or barium titanate microparticles having a surface which is partially or entirely covered by a silica layer serving as the component (A) in the curable silicone composition. Further, the organosilicon compound of the present invention preferably has a refractive index of at least 1.45, which is higher than that of an organosilicon compound primarily consisting of methyl siloxane units, which yields the advantage that the refractive index of the resulting silicone cured product will not be diminished and the transparency will not be lost. In addition, the organosilicon compound of the present invention preferably further contains a functional group which is hydrosilylation-reactive with the silicone composition, which yields the advantage that the surface-treated barium titanate microparticles or barium titanate microparticles having a surface which is partially or entirely covered by a silica layer are stably dispersed in the curable silicone composition and can be compounded in large quantities. Further, since a structure consisting of siloxane bonds (Si—O—Si), silalkylene bonds, or the like has excellent thermal stability, problems such as the yellowing or discoloration of metal oxide microparticles or the like treated using the organosilicon compound or an optical device containing the metal oxide microparticles are unlikely to arise, which yields the advantage that the heat resistance is improved.

More specifically, the organosilicon compound of the present invention is an organosilicon compound having a functional group selected from a highly polar functional group, a hydroxyl group-containing group, a silicon atom-containing hydrolyzable group, or metal salt derivatives thereof bonded to silicon atoms directly or via a functional group with a valency of (n+1) (n is a number equal to 1 or greater), and having at least one structure in the molecule in which the silicon atoms are bonded to any siloxane unit represented by R³¹₃SiO_{1/2}, R³¹₂SiO_{2/2}, R³¹SiO_{3/2}, and SiO_{4/2} (wherein R³¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1)). In addition, this organosilicon compound preferably has a refractive index of at least 1.45 at 25° C. and further contains a hydrosilylation-reactive functional group in the molecule.

A first feature of the organosilicon compound of the present invention is that the organosilicon compound has a functional group selected from a highly polar functional group, a hydroxyl group-containing group, a silicon atom-containing hydrolyzable group, or metal salt derivatives thereof bonded to silicon atoms directly or via a functional group with a valency of (n+1) (n is a number equal to 1 or greater). The functional group can modify the characteristics of the surface by interacting with the barium titanate microparticles or barium titanate microparticles having a surface which is partially or entirely covered by a silica layer and aligning, modifying, or bonding the organosilicon compound of the present invention with the surface of the barium titanate microparticles. This interaction with the surface is an interaction or bond reaction with the material surface caused by the polarity of the functional group, the formation of hydrogen bonds caused by terminal hydroxyl groups, or a bond reaction with the material surface caused by a hydrolyzable functional group, and these interactions may be applied during or after the formation of the target barium titanate microparticles or barium titanate microparticles having a surface which is partially or entirely covered by a silica layer. In particular, at the time of the treatment of barium titanate microparticles or barium titanate microparticles having a surface which is partially or entirely covered by a silica layer with high surface hydrophilicity in the untreated state, the interaction between the material surface and these functional groups is strong, which has the advantage that an excellent surface-modifying effect can be realized even when a small amount is used.

These functional groups bond to silicon atoms directly or via functional groups with a valency of (n+1) (n is a number equal to 1 or greater), but with the exception of cases in which the functional groups are hydroxyl groups (silanol groups), the functional groups preferably bond to silicon atoms via functional groups with a valency of (n+1) from the perspective of the surface-modifying effect. A functional group with a valency of (n+1) may be a linkage group with a valency of 2 or higher and is preferably a hydrocarbon group with a valency of 2 or higher which may contain hetero atoms (N, Si, O, P, S, or the like). A functional group with a valency of (n+1) may also be a linkage group with a valency of 3 or higher, and a structure in which two or more types of the same or different functional groups selected from highly polar functional groups, hydroxyl group-containing groups, silicon atom-containing hydrolyzable groups, or metal salt derivatives thereof are bonded to the linkage groups (for example, a highly polar functional group having a structure in which two carboxyl groups are bonded via trivalent functional groups) is included in the scope of the present invention.

More specifically, the functional group with a valency of (n+1) is a straight-chain or branched alkylene group which may contain hetero atoms selected from nitrogen, oxygen, phosphorus, and sulfur, an arylene group with a valency of 2 or higher, an alkenylene group with a valency of 2 or higher, an alkynylene group with a valency of 2 or higher, (poly)siloxane units, silalkylene units, or the like and is preferably a hydrocarbon group with a valency of 2 or higher to which a functional group (Q) is bonded in the alkylene portion or a portion other than the alkylene portion, the functional group (Q) being selected from a silicon atom or a highly polar functional group, a hydroxyl group-containing group, a silicon atom-containing hydrolyzable group, or metal salt derivatives thereof. The functional group with a valency of (n+1) is preferably a functional group with a valency of from 2 to 4 and is particularly preferably a divalent functional group.

The functional group (Q) bonded to silicon atoms directly or via this functional group with a valency of (n+1) (n is a number equal to 1 or greater) includes a functional group (Q) bonded to the alkylene portion, for example, and is represented by the following structural formulas. The structure may be a halogenated alkylene structure in which some of the hydrogen atoms of the alkylene portion in the formulas are substituted with halogen atoms such as fluorine, and the structure of the alkylene portion may be a straight-chain or a branched-chain structure.

### -Q

—CᵣH₂ᵣ₋ₜ₁—Cₛ₁H₍₂ₛ₁₊₁₋ₙ₎Qₙ
—CᵣH₂ᵣ-{T-Cₛ₂H₍₂ₛ₂₋ₙ₁₎Qₙ₁}ₜ₂-T-Cₛ₃H₍₂ₛ₃₊₁₋ₙ₂₎Qₙ₂
—CᵣH₂ᵣ-{T-Cₛ₂H₍₂ₛ₂₋ₙ₃₎Qₙ₃}ₜ₃-T-Cₛ₃H₂ₛ₃₊₁
—CᵣH₂ᵣ-{T-Cₛ₂H₍₂ₛ₂₋ₙ₄₎Qₙ₄}ₜ₄-T-Q
[wherein Q is the same group as described above;
r is a number within the range of from 1 to 20;
s1 is a number within the range of from 1 to 20;
s2 is a number within the range of from 0 to 20;
s3 is a number within the range of from 1 to 20;
n is the same number as described above;
t1, t2, or t4 is a number equal to 0 or greater; and
t3 is a number equal to 1 or greater.
However, (n1×t2+n2), (n3×t4), and (n4×t4+1) are respectively numbers that satisfy n; and the T moieties are independently single bonds, alkenylene groups having from 2 to 20 carbon atoms, arylene groups having from 6 to 22 carbon atoms, or divalent linkage groups represented by —CO—, —O—C(═O)—, —C(═O)—O—, —C(═O)—NH—, —O—, —S—, —O—P—, —NH—, —SiR⁹₂—, and -[SiR⁹₂O]ₜ₅— (wherein the R9 moieties are independently alkyl groups or aryl groups, and t5 is a number within the range of from 1 to 100).]

The functional group with a valency of (n+1) is particularly preferably a divalent linkage group,

examples of which include a divalent hydrocarbon group (—Z¹—) or
a group represented by -A-(R^{D2}₂SiO)ₑ₁R^{D2}₂Si—Z¹—.
Here, A and Z¹ are independently divalent hydrocarbon groups and are preferably alkylene groups having from 2 to 20 carbon atoms.
R^{D2} is an alkyl group or an aryl group and is preferably a methyl group or a phenyl group.
e1 is a number within the range of from 1 to 50, preferably within the range of from 1 to 10, and particularly preferably 1.

Q described above is a functional group selected from a highly polar functional group, a hydroxyl group-containing group, a silicon-bonded hydrolyzable group, or metal salt derivatives thereof.

Specifically, highly polar functional groups are polar functional groups containing hetero atoms (O, S, N, P, or the like) which interact with the substrate surface or reactive functional groups (including hydrophilic groups) present on the substrate surface to bond or align the organosilicon compound with the substrate surface, thereby contributing to the modification of the surface. Examples of such highly polar functional groups include functional groups having polyoxyalkylene groups, cyano groups, amino groups, imino groups, quaternary ammonium groups, carboxyl groups, ester groups, acyl groups, carbonyl groups, thiol groups, thioether groups, sulfone groups, hydrogen sulfate groups, sulfonyl groups, aldehyde groups, epoxy groups, amide groups, urea groups, isocyanate groups, phosphoric acid groups, oxyphosphoric acid groups, and carboxylic anhydride groups, or the like. These highly polar functional groups are preferably functional groups derived from amines, carboxylic acids, esters, amides, amino acids, peptides, organic phosphorus compounds, sulfonic acids, thiocarboxylic acids, aldehydes, epoxy compounds, isocyanate compounds, or carboxylic acid anhydrides.

A hydroxyl group-containing group is a hydrophilic functional group having a silanol group, an alcoholic hydroxyl group, a phenolic hydroxyl group, or a polyether hydroxyl group which typically induces dehydrative condensation or forms one or more hydrogen bonds with the substrate surface, which is an inorganic substance (M) so as to bond or align the organosilicon compound with the substrate surface, thereby contributing to the modification of the surface. Specific examples include silanol groups bonded to silicon atoms, monovalent or polyvalent alcoholic hydroxyl groups, sugar alcoholic hydroxyl groups, phenolic hydroxyl groups, and polyoxyalkylene groups having OH groups at the terminals. These are preferably functional groups derived from hydroxysilanes, monovalent or polyvalent alcohols, phenols, polyether compounds, (poly)glycerin compounds, (poly)glycidyl ether compounds, or hydrophilic sugars.

A silicon atom-containing hydrolyzable group is a functional group having at least one hydrolyzable group bonded to silicon atoms and is not particularly limited as long as the group is a silyl group having at least monovalent hydrolyzable atoms directly coupled with silicon atoms (atoms producing silanol groups by reacting with water) or monovalent hydrolyzable groups directly coupled with silicon atoms (groups producing silanol groups by reacting with water). Such a silicon atom-containing hydrolyzable group hydrolyzes to produce a silanol group, and this silanol group typically induces dehydrative condensation with the substrate surface, which is an inorganic substance (M) to form a chemical bond represented by Si—O-M (substrate surface). One or two or more of these silicon atom-containing hydrolyzable groups may be present in the organosilicon compound of the present invention, and when two or more groups are present, the groups may be of the same or different types.

A preferable example of a silicon atom-containing hydrolyzable group is a silicon atom-containing hydrolyzable group represented by —SiR⁵_{f}X_{3-f}. In the formula, R⁵ is an alkyl group or an aryl group, X is a hydrolyzable group selected from alkoxy groups, aryloxy groups, alkenoxy groups, acyloxy groups, oxime groups, amino groups, amide groups, mercapto groups, aminoxy groups, and halogen atoms, and f is a number from 0 to 2. More specifically, X is a hydrolyzable group selected from alkoxy groups such as methoxy groups, ethoxy groups, and isopropoxy groups; alkenoxy groups such as isopropenoxy groups; acyloxy groups such as acetoxy groups and benzoyloxy groups; oxime groups such as methyl ethyl ketoxime groups; amino groups such as dimethylamino groups and diethylamino groups; amide groups such as N-ethylacetamide groups; mercapto groups; aminoxy groups, and halogen atoms, and alkoxy groups having from 1 to 4 carbon atoms, (iso)propenoxy groups, or chlorine are preferable. In addition, R⁵ is preferably a methyl group or a phenyl group. Specific examples of these silicon atom-containing hydrolyzable groups include but are not limited to trichlorosilyl groups, trimethoxysilyl groups, triethoxysilyl groups, methyldimethoxysilyl groups, and dimethylmethoxysilyl groups.

Metal salt derivatives of the highly polar functional groups, hydroxyl group-containing groups, and silicon atom-containing hydrolyzable groups described above are functional groups in which some alcoholic hydroxyl groups, organic acid groups such as carboxyl groups, or —OH groups such as silonol groups, phosphoric acid groups, or sulfonic acid groups form a salt structure with a metal. Particularly preferable examples include alkali metal salts such as sodium, alkali earth metal salts such as magnesium, and aluminum salts. In these metal salt derivatives, the —O⁻ portion in the functional group electrostatically interacts with the surface of the barium titanate microparticles or barium titanate particles having a surface which is partially or entirely covered by a silica layer serving as a substrate or forms hydrogen bonds so as to bond or align the organosilicon compound with the substrate surface, which contributes to the modification of the surface.

The functional group (Q) is particularly preferably a group selected from carboxyl groups, aldehyde groups, phosphoric acid groups, thiol groups, sulfo groups, alcoholic hydroxyl groups, phenolic hydroxyl groups, amino groups, ester groups, amide groups, polyoxyalkylene groups, and silicon atom-containing hydrolyzable groups represented by —SiR⁵_{f}X_{3-f} (wherein R⁵ is an alkyl group or an aryl group, X is a hydrolyzable group selected from an alkoxy group, an aryloxy group, an alkenoxy group, an acyloxy group, a ketoxymate group, and a halogen atom, and f is a number from 0 to 2) or metal salt derivatives thereof. In particular, when the organosilicon compound of the present invention is used to post-treat the surface of barium titanate microparticles or barium titanate particles having a surface which is partially or entirely covered by a silica layer with the objective of improving the dispersibility thereof, carboxyl groups, monovalent or polyvalent alcoholic hydroxyl groups, polyoxyalkylene groups, and silicon atom-containing hydrolyzable groups represented by —SiR⁵_{f}X_{3-f} are preferably used.

A second feature of the organosilicon compound of the present invention is that silicon atoms having functional groups (Q) bonded directly or via functional groups with a valency of (n+1) (n is a number equal to 1 or greater) are bonded to a siloxane unit represented by one of R¹₃SiO_{1/2}, R¹₂SiO_{2/2}, R¹SiO_{3/2}, and SiO_{4/2}. In this siloxane portion, other siloxane units bonding to the silicon atoms may further bond to other silicon atoms or other functional groups via divalent functional groups such as siloxane bonds (Si—O—Si) or silalkylene bonds, which makes it possible to impart the organosilicon compound of the present invention with characteristics originating from a hydrophobic silicon polymer or the like. More specifically, the organosilicon compound of the present invention interacts with the surface of the barium titanate microparticles or barium titanate particles having a surface which is partially or entirely covered by a silica layer via a functional group (Q) selected from the aforementioned highly polar functional groups, hydroxyl group-containing groups, silicon atom-containing hydrolyzable groups, or metal salt derivatives thereof, and the properties of the surface such as the hydrophobicity, fine dispersibility, and dispersion stability are modified by the characteristics originating from the silicon polymer. In addition, the affinity of the entire curable silicone composition is dramatically improved by this portion, which makes it possible to add large quantities of the barium titanate microparticles or barium titanate particles having a surface which is partially or entirely covered by a silica layer in accordance with the application of the optical material.

In the formula, R¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1). Here, the substituted or unsubstituted monovalent hydrocarbon groups are preferably independently an alkyl group having from 1 to 10 carbon atoms, an alkenyl group having from 2 to 10 carbon atoms, or an aryl group or an aralkyl group having from 6 to 22 carbon atoms, and examples include straight-chain, branched, or cyclic alkyl groups such as methyl, ethyl, n-propyl, i-propyl, n-butyl, i-butyl, s-butyl, pentyl, neopentyl, cyclopentyl, and hexyl; alkenyl groups such as vinyl groups, propenyl groups, butyl groups, pentyl groups, and hexenyl groups; phenyl groups, and naphthyl groups. R¹ is industrially preferably a hydrogen atom, a methyl group, a vinyl group, a hexenyl group, a phenyl group, or a naphthyl group. In addition, the hydrogen atoms bonded to the carbon atoms of these groups of R¹ may be at least partially substituted with halogen atoms such as fluorine. Further, the functional groups selected from highly polar functional groups, hydroxyl group-containing groups, silicon atom-containing hydrolyzable groups, and metal salt derivatives thereof bonded to the silicon atoms via functional groups with a valency of (n+1) are the same groups as those described above.

The organosilicon compound of the present invention preferably has a refractive index of at least 1.45 at 25° C. for the entire molecule. Since an organosilicon compound primarily consisting of methyl siloxane units has a refractive index of less than 1.45, such a compound may reduce the refractive index of the substrate or have an adverse effect on the transparency of compounded curable resins or the like as a result of surface treatment, but the organosilicon compound of the present invention has the advantage that the compound can provide a silicone cured product with a higher refractive index and better transparency than a conventionally known surface treatment agent. The organosilicon compound of the present invention preferably has a refractive index (value measured at 25° C. and 590 nm) of at least 1.49 and more preferably at least 1.50, but an organosilicon compound having a refractive index within the range of from 1.50 to 1.60 is particularly preferable. Further, an organosilicon compound with a high refractive index of at least 1.60 can be designed by increasing the ratio of the groups selected from phenyl groups, condensed polyaromatic groups, and groups containing condensed polyaromatic groups that constitute all of the silicon atom-bonded functional groups.

The method for designing the refractive index of the organosilicon compound of the present invention so as to fall within the range described above may use a metal-containing organosilicon compound having bonds between metal atoms and silicon atoms in the molecule to provide a high refractive index, but it is industrially preferable to introduce aromatic ring-containing organic groups which provide a high refractive index as silicon-bonded functional groups. In particular, it is preferable for at least 30 mol % of all of the silicon-bonded functional groups in the organosilicon compound of the present invention to be groups selected from phenyl groups, condensed polyaromatic groups, and groups containing condensed polyaromatic groups, and this makes it possible to easily design an organosilicon compound with a refractive index of at least 1.45. Excluding the silicon atoms in the functional groups (Q), it is more preferable for at least 40 mol % of the monovalent functional groups bonded to all of the silicon atoms in the molecule to be groups selected from phenyl groups, condensed polyaromatic groups, and groups containing condensed polyaromatic groups, and it is particularly preferable for from 40 to 80 mol % to be phenyl groups or naphthyl groups. The refractive index of the organosilicon compound increases as the ratio of these functional groups that are introduced increases, and an organosilicon compound into which the same number of naphthyl groups have been introduced tends to exhibit a higher refractive index than an organosilicon compound into which the same number of phenyl groups have been introduced.

The organosilicon compound of the present invention has at least two silicon atoms in the molecule as a result of having the structure described above, but from the perspective of the modification of the surface of the substrate, it is preferable for the organosilicon compound of the present invention to have from 2 to 1000 silicon atoms in the molecule. However, when the functional groups (Q) are silicon atom-containing hydrolyzable groups, it is preferable to have from 2 to 1000 silicon atoms in the molecule, excluding the silicon atoms in the functional groups (Q). Here, the number of silicon atoms in the organosilicon compound excluding the silicon atoms in the functional groups (Q) is more preferably from 2 to 500 atoms. The range of from 2 to 200 atoms is more preferable, and the range of from 2 to 100 atoms is particularly preferable.

In particular, the component (B) is preferably used for the surface treatment of the barium titanate microparticles or barium titanate microparticles having a surface which is partially or entirely covered by a silica layer serving as the component (A) and is preferably used for post treatment with the objective of improving the dispersibility thereof, so the number of silicon atoms in the organosilicon compound of the present invention is more preferably from 3 to 500 atoms and even more preferably within the range of from 5 to 200 atoms, and the range of from 7 to 100 atoms is particularly preferable. Further, the component (B) of the present invention may also combine an organosilicon compound having a relatively large number of silicon atoms and an organosilicon compound having a relatively small number of silicon atoms in accordance with the particle size, treatment method, or the like of the component (A) used for treatment.

From the perspective of modifying the surface, it is preferable for at least 50 mol % of all of the monovalent functional groups bonded to silicon atoms to be monovalent hydrocarbon groups, and it is particularly preferable for at least 75 mol % of all of the monovalent functional groups bonded to silicon atoms to be monovalent hydrocarbon groups. Further, it is preferable for the number of silicon atoms having the functional groups (Q) bonded directly or via functional groups with a valency of (n+1) (n is a number equal to 1 or greater) in the organosilicon compound of the present invention (excluding the silicon atoms in the functional groups (Q)) to be a number no greater than ⅓ the number of all of the silicon atoms in the molecule (excluding the silicon atoms in the functional groups (Q)). From the perspective of modifying the surface of the optical material, the number is preferably at most ⅕, more preferably at most 1/10, and particularly preferably at most 1/20 the number of all of the silicon atoms in the molecule. At this time, it is preferable for at least 90 mol % of all of the monovalent functional groups bonded to silicon atoms to be monovalent hydrocarbon groups, and it is preferable for at least 30 mol % to be groups selected from phenyl groups, condensed polyaromatic groups, and groups containing condensed polyaromatic group. The other monovalent hydrocarbon groups are preferably selected from methyl groups, vinyl groups, and hexenyl groups. From the perspective of the refractive index, it is particularly preferable for from 40 to 80 mol % of all of the monovalent functional groups to be phenyl groups or naphthyl groups.

The organosilicon compound aligns, modifies, or bonds to the surface of the surface-treated barium titanate microparticles or barium titanate microparticles having a surface which is partially or entirely covered by a silica layer, but by having reactive sites in the composition cured by a hydrosilylation reaction at this time, the compound is efficiently incorporated into the curing system for each treatment substrate, which yields the advantage that the dispersion stability and compounding stability are improved. Therefore, the organosilicon compound of the present invention preferably has a hydroxilylation-reactive functional group in the molecule. The number in the molecule, type, and binding sites of this functional group is not limited, but there is preferably at least one functional group in the molecule, and examples of hydrosilylation-reactive functional groups include silicon-bonded hydrogen atoms, alkenyl groups, and acyloxy groups. In particular, in the present invention, there are preferably from 1 to 10 hydrosilylation-reactive functional groups in the molecule, and the compound preferably contains silicon-bonded hydrogen atoms or alkenyl groups having from 2 to 10 carbon atoms, or acyloxy groups having from 3 to 12 carbon atoms at the terminals or side chains of the polysiloxane portion.

Such an organosilicon compound may employ a straight-chain, branched-chain, reticulated (network), or ring-shaped molecular structure and is represented by the following average structural formula, including cases in which the compound contains bonds mediated by divalent functional groups between Si moieties of siloxane bonds or silalkylene bonds in the molecule.

(R^{M}₃SiO_{1/2})ₐ(R^{D}₂SiO_{2/2})_{b}(R^{T}SiO_{3/2})_{c}(SiO_{4/2})_{d}

In the formula, R^{M}, R^{D} and R^{T} are independently

monovalent hydrocarbon groups, hydrogen atoms, hydroxyl groups, alkoxy groups, groups having functional groups (Q) selected from highly polar functional groups, hydroxyl group-containing groups, silicon atom-containing hydrolyzable groups, or metal salt derivatives thereof bonded to silicon atoms directly or via functional groups with a valency of (n+1) represented by —Z-(Q)n described above, or divalent functional groups bonded to the Si atoms of other siloxane units. Here, the monovalent hydrocarbon groups are the same groups as described above, and examples of the divalent functional groups bonded to the Si atoms of other siloxane units include but are not limited to alkylene groups having from 2 to 20 carbon atoms and aralkylene groups having from 8 to 22 carbon atoms. From an industrial perspective and the perspective of modifying the surface of the optical material, it is preferable for at least 50 mol % of all of the R^{M}, R^{D}, and R^{T} moieties to be monovalent hydrocarbon groups, and it is particularly preferable for at least 75 mol % to be monovalent hydrocarbon groups. In addition, in order to improve the refractive index, it is more preferable for at least 30 mol % of all of the R^{M}, R^{D}, and R^{T} moieties to be selected from phenyl groups, condensed polyaromatic groups, and groups containing condensed polyaromatic groups. In addition, it is even more preferable for at least one of all of the R^{M}, R^{D}, and R^{T} moieties to be a hydrosilylation-reactive functional group.

At least one of all of the R^{M}, R^{D}, and R^{T} moieties is a group having a functional group (Q) selected from highly polar functional groups, hydroxyl group-containing groups, silicon atom-containing hydrolyzable groups, or metal salt derivatives thereof bonded to silicon atoms directly or via functional groups with a valency of (n+1), wherein n is a number equal to 1 or greater, a to d are respectively 0 or positive numbers, and a+b+c+d is a number within the range of from 2 to 1000. Here, a+b+c+d is preferably from 2 to 500 and more preferably from 2 to 100. In addition, when used to post-treat the surface of an optical fine member with the objective of improving the dispersibility thereof, a+b+c+d is more preferably from 3 to 500, even more preferably within the range of from 5 to 200, and particularly preferably within the range of from 7 to 100. At this time, the number of silicon atoms having the functional groups (Q) in the average structural formula described above (x, excluding the silicon atoms in the functional groups (Q)) is preferably a number equal to at most ⅓ of a+b+c+d. From the perspective of modifying the surface of the optical material, the number is more preferably at most ⅕, even more preferably at most 1/10, and particularly preferably at most 1/20 of a+b+c+d.

The organosilicon compound of the present invention particularly preferably has an essentially hydrophobic main chain siloxane structure consisting of straight-chain or branched-chain siloxane bonds or silalkylene bonds and has functional groups (Q) selected from highly polar functional groups, hydroxyl group-containing groups, silicon atom-containing hydrolyzable groups, or metal salt derivatives thereof bonded to silicon atoms of the side chains (including structures that are branched via silalkylene bonds or the like) or terminals directly or via functional groups with a valency of (n+1). At this time, with the objective of imparting advanced hydrophobicity or the like, a molecular design may be—and is preferably—employed so that the compound has a highly branched siloxane dendron structure or a siloxane macromonomer structure having a constant chain length. These hydrophobic siloxane structures and main chain siloxane structures are preferably bonded by divalent hydrocarbon groups such as silalkylenes.

Such an organosilicon compound is represented by the following average structural formula.

(R^{M1}₃SiO_{1/2})ₐ₁(R^{D1}₂SiO_{2/2})_{b1}(R^{T1}SiO_{3/2})_{c1}(SiO_{4/2})_{d1}

In the formula, R^{M1}, R^{D1}, and R^{T1} are independently groups selected from:

monovalent hydrocarbon groups, hydrogen atoms, hydroxyl groups, alkoxy groups, groups having functional group (Q) selected from highly polar functional groups, hydroxyl group-containing groups, silicon atom-containing hydrolyzable groups, or metal salt derivatives thereof bonded to silicon atoms via divalent functional groups (Z¹) represented by —Z¹-Q;
groups represented by -A-(R^{D2}₂SiO)ₑ₁R^{D2}₂Si—Z¹-Q (wherein A is a divalent hydrocarbon group, R^{D2} is an alkyl group or a phenyl group, e1 is a number within the range of from 1 to 50, and Z¹ and Q are the same groups as described above);
groups represented by -A-(R^{D2}₂SiO)ₑ₁SiR^{M2}₃ (wherein A and R^{D2} are the same groups as described above, R^{M2} is an alkyl group or a phenyl group, and e1 is the same number as described above); or
groups represented by —O—Si(R^{D3})₂—X¹ (wherein R^{D3} is an alkyl group having from 1 to 6 carbon atoms or a phenyl group, and X¹ is a silylalkyl group represented by the following general formula (2) when i=1):

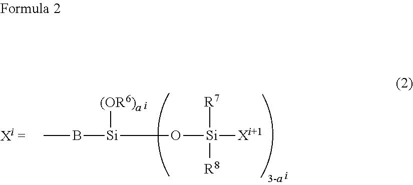

(wherein R⁶ is a hydrogen atom or an alkyl group having from 1 to 6 carbon atoms or phenyl group, and R⁷ or R⁸ is a hydrogen atom or an alkyl group or phenyl group having from 1 to 6 carbon atoms; B is a straight-chain or branched-chain alkylene group represented by CᵣH₂ᵣ; r is an integer from 2 to 20;
i represents the hierarchies of a silylalkyl group represented by Xⁱ, which is an integer from 1 to c when the number of hierarchies is c; the number of hierarchies c is an integer from 1 to 10; a′ is an integer from 0 to 2 when i is 1 and is a number less than 3 when i is 2 or greater; Xⁱ⁺¹ is a silylalkyl group when i is less than c and is a methyl group (—CH₃) when i=c).

Here, the monovalent hydrocarbon groups are the same groups as described above, and examples of the divalent hydrocarbon groups serving as A include but are not limited to alkylene groups having from 2 to 20 carbon atoms and aralkylene groups having from 8 to 22 carbon atoms. In addition, the silylalkyl group represented by X¹ is known as a carbosiloxane dendrimer structure, an example of which is a group using a polysiloxane structure as a skeleton and having a highly branched structure in which siloxane bonds and silalkylene bonds are arranged alternately, as described in Japanese Unexamined Patent Application Publication No. 2001-213885.

It is preferable for at least 50 mol % of all of the R^{M1}, R^{D1}, and R^{T1} moieties to be monovalent hydrocarbon groups, and at least one group represented by —Z¹-(Q)n or a group represented by -A-^{D2}₂SiO)ₑ₁R^{D2}₂Si—Z¹-(Q)n is contained in the molecule. Further, in order to improve the refractive index, it is preferable for at least 30 mol % of all of the R^{M1}, R^{D1}, and R^{T1} moieties to be groups selected from phenyl groups, condensed polyaromatic groups, and groups containing condensed polyaromatic groups, and it is particularly preferable for from 40 to 80 mol % to be phenyl groups or naphthyl groups. In addition, it is more preferable for at least one of all of the R^{M}, R^{D}, and R^{T} moieties to be a hydrosilylation-reactive functional group, and it is particularly preferable for from 1 to 10 moieties to be silicon-bonded hydrogen atoms, alkenyl groups having from 2 to 10 carbon atoms, or acyloxy groups having from 3 to 12 carbon atoms.

a1 to d1 are respectively 0 or positive numbers, and a1+b1+c1+d1 is a number within the range from 2 to 500. In addition, the number of silicon atoms in the molecule, including siloxane portions that are branched via other divalent hydrocarbon groups, is within the range of from 2 to 1000. In particular, when the silicon compound of the present invention is used to post-treat the surface of the barium titanate microparticles or barium titanate microparticles having a surface which is partially or entirely covered by a silica layer with the objective of improving the dispersibility thereof, the number of silicon atoms in the organosilicon compound of the present invention is a number in which a1+b1+c1+d1 is within the range of from 3 to 500, and the number of silicon atoms in the organosilicon compound is preferably within the range of at most 500 atoms. Further, it is more preferable for a1+b1+c1+d1 to be a number within the range of from 5 to 200 and for the number of silicon atoms in the organosilicon compound to be a number within the range of at most 200 atoms. It is most preferable for a1+b1+c1+d1 to be a number within the range of from 7 to 100 and for the number of silicon atoms in the organosilicon compound to be a number within the range of at most 100 atoms. At this time, the number of silicon atoms having the functional groups (Q) in the average structural formula described above (x, excluding the silicon atoms in the functional groups (Q)) is preferably a number equal to at most ⅓ of the number of silicon atoms in the organosilicon compound. >From the perspective of the surface modification described above, the number is more preferably at most ⅕, even more preferably at most 1/10, and particularly preferably at most 1/20 of the number of silicon atoms in the organosilicon compound.

Such an organosilicon compound of the present invention has an essentially hydrophobic main chain siloxane structure consisting of straight-chain or branched-chain siloxane bonds or silalkylene bonds represented by the following structural formulas (3-1) to (3-5), examples of which include organic silico compounds having functional groups (Q) selected from highly polar functional groups, hydroxyl group-containing groups, silicon atom-containing hydrolyzable groups, or metal salt derivatives thereof bonded to silicon atoms of the side chains (including structures that are branched via silalkylene bonds or the like) or terminals directly or via functional groups with a valency of (n+1).

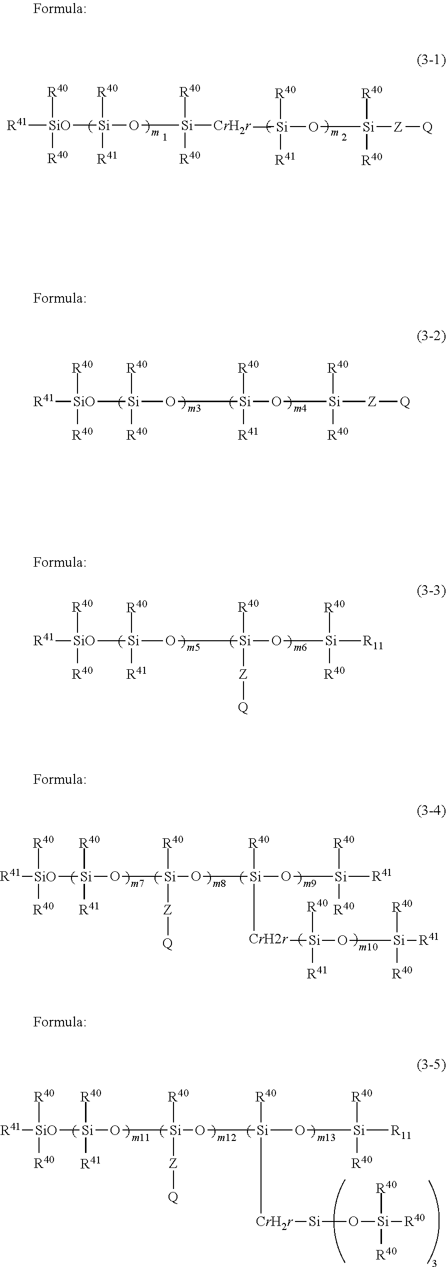

In the formula, —Z-Q is the same group as described above; the R⁴⁰ moieties; are independently methyl groups, phenyl groups, or naphthyl groups; and the R⁴¹ moieties are independently monovalent functional groups selected from hydrogen atoms, alkyl groups having from 1 to 20 carbon atoms, alkenyl groups having from 2 to 22 carbon atoms, phenyl groups, and naphthyl groups, and groups represented by —Z-Q.

In formula (3-1), m1 and m2 are respectively numbers equal to 1 or greater, wherein m1+m2 is preferably a number within the range of from 2 to 400, and m1 and m2 are particularly preferably numbers within the ranges of from 2 to 200 and from 1 to 100, respectively. In formula (3-1), r is a number within the range of from 1 to 20 and is preferably a number within the range of from 2 to 12. With the objective of improving the compounding stability in a hydrosilylation reaction-curable silicone resin, it is particularly preferable for at least one of the functional groups represented by R⁴¹ to be an alkenyl group having from 2 to 22 carbon atoms or a hydrogen atom. Further, with the objective of increasing the refractive index of the organosilicon compound, it is preferable for at least 40 mol % of all of the R⁴⁰ and R⁴¹ moieties to be phenyl groups or naphthyl groups. In addition, the number of silicon atoms to which the groups represented by —Z-Q are bonded is preferably a number equal to at most ⅓ the number of silicon atoms in the organosilicon compound represented by formula (3-1) (excluding the silicon atoms in the functional groups (Q)) and, from the perspective of modifying the optical material, is more preferably a number equal to at most ⅕ the number of silicon atoms in the organosilicon compound.

In formula (3-2), m3 and m4 are respectively numbers equal to 0 or greater, wherein m3+m4 is preferably a number within the range of from 0 to 400, and m3 and m4 are particularly preferably numbers within the ranges of from 2 to 300 and from 0 to 100, respectively. With the objective of improving the compounding stability in a hydrosilylation reaction-curable silicone resin, it is particularly preferable for at least one of the functional groups represented by R⁴¹ to be an alkenyl group having from 2 to 22 carbon atoms or a hydrogen atom. Further, with the objective of increasing the refractive index of the organosilicon compound, it is preferable for at least 40 mol % of all of the R⁴⁰ and R⁴¹ moieties to be phenyl groups or naphthyl groups. In addition, the number of silicon atoms to which the groups represented by —Z-Q are bonded is preferably a number equal to at most ⅓ the number of silicon atoms in the organosilicon compound represented by formula (3-2) (excluding the silicon atoms in the functional groups (Q)) and, from the perspective of modifying the surface pf the optical material, is more preferably a number equal to at most ⅕ the number of silicon atoms in the organosilicon compound.

In formula (3-3), m5 is a number equal to 0 or greater, m6 is a number equal to 1 or greater, wherein m5+m6 is preferably a number within the range of from 1 to 400, and m5 and m4 are particularly preferably numbers within the ranges of from 0 to 300 and from 1 to 10, respectively. With the objective of improving the compounding stability in a hydrosilylation reaction-curable silicone resin, it is particularly preferable for at least one of the functional groups represented by R⁴¹ to be an alkenyl group having from 2 to 22 carbon atoms or a hydrogen atom. Further, with the objective of increasing the refractive index of the organosilicon compound, it is preferable for at least 40 mol % of all of the R⁴⁰ and R⁴¹ moieties to be phenyl groups or naphthyl groups. In addition, the number of silicon atoms to which the groups represented by —Z-Q are bonded is preferably a number equal to at most ⅓ the number of silicon atoms in the organosilicon compound represented by formula (3-3) (excluding the silicon atoms in the functional groups (Q)) and, from the perspective of modifying the optical material, is more preferably a number equal to at most ⅕ the number of silicon atoms in the organosilicon compound.

In formula (3-4), m7 is a number equal to 0 or greater, m8 and m9 are respectively numbers equal to 1 or greater, and m10 is a number within the range of from 1 to 50. It is preferable for m7+m8+m9 to be a number within the range of from 2 to 400. It is also preferable for m7 to be a number within the range of from 2 to 200 and for m8 or m9 to respectively be a number within the range of from 1 to 100. In formula (3-4), r is a number within the range of from 1 to 20 and is preferably a number within the range of from 2 to 12. In addition, with the objective of improving the compounding stability in a hydrosilylation reaction-curable silicone resin, it is preferable for at least one of the functional groups represented by R⁴¹ to be an alkenyl group having from 2 to 22 carbon atoms or a hydrogen atom. Further, with the objective of increasing the refractive index of the organosilicon compound, it is preferable for at least 40 mol % of all of the R⁴⁰ and R⁴¹ moieties to be phenyl groups or naphthyl groups. In addition, the number of silicon atoms to which the groups represented by —Z-Q are bonded is preferably a number equal to at most ⅓ the number of silicon atoms in the organosilicon compound represented by formula (3-4) (excluding the silicon atoms in the functional groups (Q)) and, from the perspective of modifying the surface of the optical material, is more preferably a number equal to at most ⅕ the number of silicon atoms in the organosilicon compound.

The structure represented by formula (3-5) has a carbosiloxane dendrimer structure in the molecule, wherein m11 is a number equal to 0 or greater, m12 is a number equal to 1 or greater, and m13 is a number equal to 1 or greater. It is preferable for m11+m12+m13 to be a number within the range of from 2 to 400, and it is particularly preferable for m11 to be a number within the range of from 2 to 200 and for m8 or m9 to respectively be a number within the range of from 1 to 100. In formula (3-5), r is a number within the range of from 1 to 20 and is preferably a number within the range of from 2 to 12. In addition, with the objective of improving the compounding stability in a hydrosilylation reaction-curable silicone resin, it is particularly preferable for at least one of the functional groups represented by R⁴¹ to be an alkenyl group having from 2 to 22 carbon atoms or a hydrogen atom. Further, with the objective of increasing the refractive index of the organosilicon compound, it is preferable for at least 40 mol % of all of the R⁴⁰ and R⁴¹ moieties to be phenyl groups or naphthyl groups. In addition, the number of silicon atoms to which the groups represented by —Z-Q are bonded is preferably a number equal to at most ⅓ the number of silicon atoms in the organosilicon compound represented by formula (3-5) (excluding the silicon atoms in the functional groups (Q)) and, from the perspective of modifying the surface of the optical material, is more preferably a number equal to at most ⅕ the number of silicon atoms in the organosilicon compound.

The production method of the organosilicon compound of the present invention is not particularly limited, but the compound can be obtained, for example, by reacting a siloxane raw material having a reactive group such as an alkenyl group, an amino group, a halogen atom, or a hydrogen atom in the molecule and preferably having a refractive index of at least 1.45 and an organic compound or an organosilicon compound having a group that is reactive with the functional groups (Q) described above in the presence of a catalyst. By adjusting the reaction ratio of the structure of the siloxane raw material and the compound having the functional groups (Q), it is possible to adjust the number of functional groups (Q) introduced into the molecule and to leave behind hydrosilylation-reactive functional groups such as alkenyl groups.

In the curable silicon composition of the present invention, the component (A) preferably comprises barium titanate microparticles or barium titanate microparticles having a surface which is partially or entirely covered by a silica layer surface-treated by the component (B). Examples of methods for treating the surface of the component (A) with the component (B) include a method of spraying the component (B) or a solution thereof (containing a product dispersed in an organic solvent) at a temperature from room temperature to 200° C. while stirring the component (A) with an agitator and then drying the mixture; a method of mixing the component (A) and the component (B) or a solution thereof in an agitator (including a grinding device such as a ball mill or a jet mill, an ultrasonic dispersing device, and the like) and then drying the mixture; and a treatment method of adding a treatment agent to a solvent, dispersing a powder so that the powder is adsorbed by the surface, and then drying and sintering the mixture. Another example is a method of adding other the silicone components constituting the curable silicone of the present invention, the component (A), and the component (B) and then treating the surface in-situ (integral blending method). When treating the surface of the component (A), the amount of the component (B) that is added is preferably from 0.1 to 500 parts by weight, particularly preferably from 1.0 to 250 parts by weight, and most preferably within the range of from 5.0 to 100 parts by weight per 100 parts by weight of the component (B). In particular, in the case of the treatment of microparticles with a small particle size of less than a few tens of nm, it is preferable to add at least 100 parts by weight to 100 parts by weight of the component (A).

In the surface treatment methods described above, the device used to stir the components (A) and (B) is not particularly limited, and two or more types of dispersing devices may also be used in separate stages. Specific examples of devices used for dispersion and stirring include a homo mixer, a paddle mixer, a Henschel mixer, a line mixer, a homo disper, a propeller agitator, a vacuum kneader, a homogenizer, a kneader, a dissolver, a high-speed dispenser, a sand mill, a roll mill, a ball mill, a tube mill, a conical mill, an oscillating ball mill, a high swing ball mill, a jet mill, an attritor, a dyno mill, a GP mill, a wet atomization device (Altimizer or the like manufactured by Sugino Machines), an ultrasonic dispersion device (ultrasonic homogenizer), a bead mill, a Banbury mixer, a stone mortar mill, and a grindstone-type pulverizer. In particular, in order to disperse inorganic particles into fine particles with an average particle size of at most 100 nm, dispersion with an ultrasonic dispersion device or bead mill which promotes dispersion of beans by the shearing force caused by the friction of minute beads is preferable. Examples of such a bead mill include the “Ultra Apex Mill” (trade name) manufactured by Kotobuki Industries (Ltd.) and the “Star Mill” (trade name) manufactured by Ashizawa Fine Tech (Ltd.). The beads that are used are preferably glass beads, zirconia beads, alumina beads, magnetic beads, styrene beads, or the like. When an ultrasonic dispersion device is used, it is preferable to use an ultrasonic homogenizer with a rated output of at least 300 W. These ultrasonic homogenizers are commercially available from Nippon Seiki Co., Ltd., Mitsui Electric Co., Ltd., or the like.

Further, when the component (B) is an organosilicon compound having at least one condensation-reactive functional group or hydrosilylation-reactive functional group in the molecule, the component may be used not only as a surface treatment agent for the component (A), but also as part of the main agent of the composition, as with the components (C) and (D). Specifically, the entire composition may be cured by following a method of adding the aforementioned organosilicon compound having at least one condensation-reactive functional group or hydrosilylation-reactive functional group in the molecule as the curable silicone composition of the present invention, a reactive silicone serving as a cross-linking agent (described below), a substrate, and a curing reaction catalyst and treating the surface of the optical material in-situ (integral blending method). In particular, since the organosilicon compound of the present invention has excellent compounding stability with respect to silicone materials, the dispersibility and thermal stability of the substrate in the cured product are particularly favorable after the curing reaction when the material has a high refractive index of at least 1.50, which yields the advantage that the entire cured product is uniform and has a high refractive index.

For example, preparing a curable silicone composition containing the component (A) surface-treated by the organosilicon compound of the present invention by uniformly mixing the component (A), the component (C) having at least one alkenyl group or acyloxy group in the molecule, and the components (C) to (E) described below and curing the composition by heating or the like is included in the preferred embodiments of the present invention.

<Hydrosilation Reaction Curable Silicone Composition>

As described above, the curable silicon composition of the present invention contains barium titanate microparticles or barium titanate microparticles having a surface which is partially or entirely covered by a silica layer serving as the component (A) surface-treated by the component (B), wherein the refractive index of the cured product is at least 1.55. Here, the hydrosilylation reaction-curable composition typically contains an organopolysiloxane having at least two hydrosilylation reactive functional groups in each molecule and a hydrosilylation reaction catalyst. Further in order to increase the refractive index of the cured product, an aryl group such as a phenyl group or a naphthyl group is preferably introduced into an organopolysiloxane serving as a structural component.

In addition to the components (A) and (B) described above, the curable silicon composition of the present invention is preferably a hydrosilylation reaction-curable silicone composition containing:

(C) an organopolysiloxane having at least two alkenyl groups in each molecule;
(D) an organopolysiloxane having at least two silicon-bonded hydrogen atoms in each molecule; and
(E) a hydrosilylation reaction catalyst.

<Component (C)>

Component (C) is an organopolysiloxane having at least two alkenyl groups in each molecule and is not particularly limited. Examples of the alkenyl groups in the component (C) include vinyl groups, allyl groups, butenyl groups, pentenyl groups, hexenyl groups, and heptenyl groups. Of these, vinyl groups and hexenyl groups are preferable. Non-alkenyl groups in the component (C) bonding to the silicon atom are exemplified by alkyl groups such as a methyl group, an ethyl group, a propyl group, a butyl group, a pentyl group, a hexyl group, a heptyl group, and the like; aryl groups such as a phenyl group, a tolyl group, a xylyl group, a naphthyl group, and the like; aralkyl groups such as a benzyl group, a phenethyl group, and the like; and halogenated alkyl groups such as a chloromethyl group, a 3-chloropropyl group, a 3,3,3-trifluoropropyl group, and the like; and such non-alkenyl groups are preferably the methyl group or phenyl group. The component (C) may have a straight, branched, cyclic, net-like, or a partially branched straight chain molecular structure.

This type of organopolysiloxane of the component (C) is exemplified by a copolymer of dimethylsiloxane and methylvinylsiloxane capped at both molecular terminals with trimethylsiloxy groups; methylvinylpolysiloxane capped at both molecular terminals with trimethylsiloxy groups; copolymer of dimethylsiloxane, methylvinylsiloxane and methylphenylsiloxane capped at both molecular terminals with trimethylsiloxy groups; dimethylpolysiloxane capped at both molecular terminals with dimethylvinylsiloxy groups; methylvinylpolysiloxane capped at both molecular terminals with dimethylvinylsiloxy groups; copolymers of dimethylsiloxane and methylvinylsiloxane capped at both molecular terminals with dimethylvinylsiloxy groups; copolymer of dimethylsiloxane, methylvinylsiloxane and methylphenylsiloxane capped at both molecular terminals with dimethylvinylsiloxy groups; organopolysiloxane copolymers composed of siloxane units represented by the general formula R′₃SiO_{1/2} and siloxane units represented by the general formula R′₂R″SiO_{1/2} and siloxane units represented by the formula SiO_{4/2}, organopolysiloxane copolymers composed of siloxane units represented by the general formula R′₂R″SiO_{1/2} and siloxane units represented by the formula SiO_{4/2}, organopolysiloxane copolymers composed of siloxane units represented by the general formula R′R″SiO_{2/2} and siloxane units represented by the general formula R′SiO_{3/2} and siloxane units represented by the general formula R″SiO_{3/2}, and mixtures of two or more such organopolysiloxanes. Furthermore, R′ in the formula is synonymous with the groups described above. Furthermore, R″ in the formula is an alkenyl group and is exemplified by a vinyl group, an allyl group, a butenyl group, a pentenyl group, a hexenyl group, and a heptenyl group.

<Component (D)>

No particular limitation is placed on the organopolysiloxane of the component (D) as long as the organopolysiloxane has a silicon-bonded hydrogen atom. Examples of the bond positions of the silicon-bonded hydrogen atoms in the component (D) are molecular chain terminals and/or molecular side chains. The other groups bonded to the silicon atom in the component (D) are exemplified by alkyl groups such as a methyl group, an ethyl group, a propyl group, a butyl group, a pentyl group, a hexyl group, a heptyl group, and the like; aryl groups such as a phenyl group, a tolyl group, a xylyl group, a naphthyl group, and the like; aralkyl groups such as a benzyl group, a phenethyl group, and the like; and halogenated alkyl groups such as a chloromethyl group, a 3-chloropropyl group, a 3,3,3-trifluoropropyl group, and the like; and such other groups are preferably the methyl group or phenyl group. The component (D) may have a straight, branched, cyclic, net-like, or a partially branched straight chain molecular structure.

This type of component (D) organopolysiloxane is exemplified by a methylhydrogenpolysiloxane capped at both molecular terminals with trimethylsiloxy groups; a copolymer of dimethylsiloxane and methyl hydrogen siloxane capped at both molecular terminals with trimethylsiloxy groups; a copolymer of dimethylsiloxane, methylhydrogensiloxane and methylphenylsiloxane capped at both molecular terminals with trimethylsiloxy groups; a dimethylpolysiloxane capped at both molecular terminals with dimethylhydrogensiloxy groups; a copolymer of dimethylsiloxane and methylphenylsiloxane capped at both molecular terminals with dimethylhydrogensiloxy groups; a methylphenylpolysiloxane capped at both molecular terminals with dimethylhydrogensiloxy groups; organopolysiloxane copolymers composed of siloxane units represented by the general formula R′₃SiO_{1/2} and siloxane units represented by the general formula R′₂HSiO_{1/2} and siloxane units represented by the formula SiO_{4/2}, organopolysiloxane copolymers composed of siloxane units represented by the general formula R′₂HSiO_{1/2} and siloxane units represented by the formula SiO_{4/2}, organopolysiloxane copolymers composed of siloxane units represented by the general formula R′HSiO_{2/2}, organopolysiloxane copolymers composed of siloxane units represented by the general formula R′SiO_{3/2} or siloxane units represented by the formula HSiO_{3/2}, and mixtures of two or more such organopolysiloxanes. Furthermore, R′ in the formula is an alkyl group such as a methyl group, an ethyl group, a propyl group, a butyl group, a pentyl group, a hexyl group, a heptyl group, and the like; an aryl group such as a phenyl group, a tolyl group, a xylyl group, naphthyl group, and the like; an aralkyl group such as a benzyl group, a phenethyl group, and the like; or a halogenated alkyl group such as a chloromethyl group, a 3-chloropropyl group, a 3,3,3-trifluoropropyl group, and the like.

The component (C) or component (D) is an organopolysiloxane having a hydrosilylation-reactive functional group, some or all of which is represented by the following average unit formula:

(R²¹₃SiO_{1/2})ₐ(R²¹₂SiO_{2/2})_{b}(R²²SiO_{3/2})_{c}(SiO_{4/2})_{d}

(wherein the R²¹ moieties are alkyl groups, alkenyl groups, phenyl groups, or hydrogen atoms; the R²² moieties are groups represented by R²¹, condensed polyaromatic groups, or groups including a condensed polyaromatic group, provided that at least two of the R²¹ or R²² moieties in the molecule are alkenyl groups or hydrogen atoms and at least one R² moiety in the molecule is a condensed polyaromatic group or a group including a condensed polyaromatic group; and a, b, c, and d are numbers satisfying the formulae: 0.01≦a≦0.8, 0≦b≦0.5, 0.2≦c≦0.9, 0≦d<0.2, and a+b+c+d=1).

This organopolysiloxane has a condensed polyaromatic group such as a naphthyl group or a group containing a condensed polyaromatic group in the molecule, so the organopolysiloxane is cured by a hydrosilylation reaction and has a high refractive index, high transparency, and high heat resistance, which yields the advantage that it is possible to provide a curable silicone composition which forms a cured product having low water vapor permeability.

In the formula, the R²¹ moieties are alkyl groups, alkenyl groups, phenyl groups or hydrogen atoms. Examples of the alkyl group of R²¹ include a methyl group, an ethyl group, a propyl group, and a butyl group. Of these, a methyl group is preferable. Examples of the alkenyl group of R²¹ include a vinyl group, an allyl group, and a butenyl group. Of these, a vinyl group is preferable.

In the formula, R²² is an alkyl group, an alkenyl group, a phenyl group, a hydrogen atom, or is a condensed polyaromatic group or a group including a condensed polyaromatic group. Examples of the alkyl group of R²² include the groups represented by R²¹. Examples of the alkenyl group of R²² include the groups represented by R¹. Examples of the condensed polyaromatic group of R²² include a naphthyl group, an anthracenyl group, a phenanthryl group, a pyrenyl group, and such condensed polyaromatic groups where a hydrogen atom is replaced by an alkyl group such as a methyl group, an ethyl group, and the like; by an alkoxy group such as a methoxy group, an ethoxy group, and the like; or by a halogen atom such as a chlorine atom, a bromine atom, and the like. The condensed polyaromatic group is preferably the naphthyl group. Examples of the group including a condensed polyaromatic group of R² include alkyl groups including a condensed polyaromatic group such as a naphthyl ethyl group, a naphthyl propyl group, an anthracenyl ethyl group, a phenanthryl ethyl group, a pyrenyl ethyl group, and the like; and such groups where a hydrogen atom in the condensed polyaromatic group is replaced by an alkyl group such as a methyl group, an ethyl group, and the like; by an alkoxy group such as a methoxy group, an ethoxy group, and the like; or by a halogen atom such as a chlorine atom, a bromine atom, and the like.

Further, in the formula, at least one of the R¹ or R² moieties in one molecule is an alkenyl group or hydrogen atom. Moreover, in the formula, at least one R² moiety in one molecule is a condensed polyaromatic group or a group including a condensed polyaromatic group. Preferably, at least 50 mol % of the R² moieties in one molecule are condensed polyaromatic groups or a group including a condensed polyaromatic group.

Further, in the formula, a, b, c, and d are numbers that satisfy the formulae: 0.01≦a≦0.8, 0≦b≦0.5, 0.2≦c≦0.9, 0≦d<0.2, and a+b+c+d=1. Preferably, a, b, c, and d are numbers that satisfy the formulae: 0.05≦a≦0.7, 0≦b≦0.4, 0.3≦c≦0.9, 0≦d<0.2, and a+b+c+d=1. Particularly preferably, a, b, c, and d are numbers that satisfy the formulae: 0.1≦a≦0.6, 0≦b≦0.3, 0.4≦c≦0.9, 0≦d<0.2, and a+b+c+d=1. When the value of a is below the lower limit of the range described above, the obtained organopolysiloxane changes from the liquid state to solid state, and handling and processability declines. On the other hand, transparency of the obtained cured product declines if a exceeds the upper limit of the range described above. Further, stickiness of the obtained cured product occurs when b exceeds the upper limit of the range described above. Further, the refractive index of the obtained cured product may markedly decline if c is less than the lower limit of the range described above. On the other hand, the cured product becomes excessively rigid and brittle if c exceeds the upper limit of the range described above. Further, the cured product becomes extremely rigid and brittle if d exceeds the upper limit of the range described above.

<Component (E)>

Component (E) is a hydrosilylation reaction catalyst, examples of which include platinum-based catalysts, rhodium-based catalysts, and palladium-based catalysts. Platinum-based catalysts are preferred due to the ability to substantially promote the curing of the present composition. Examples of the platinum-based catalyst include a platinum fine powder, chloroplatinic acid, an alcohol solution of chloroplatinic acid, a platinum-alkenylsiloxane complex, a platinum-olefin complex and a platinum-carbonyl complex, with a platinum-alkenylsiloxane complex being preferred.

In this composition, the amounts of the components (C) and (D) are not particularly limited, but the amounts preferably result in a mole ratio of silicon-bonded hydrogen atoms relative to alkenyl groups in the composition being within the range of from 0.1 to 5 and particularly preferably within the range of from 0.5 to 2.

In the present composition, the content of the component (E) is not particularly limited as long as the curing of the composition can be accelerated. Specifically, the content is preferably an amount with which the catalyst metal in the component (E) is within the range of from 0.01 to 500 ppm, even more preferably within the range of from 0.01 to 100 ppm, and yet even more preferably within the range of from 0.01 to 50 ppm in weight units with respect to the above composition.

The present composition may also contain an adhesion-imparting agent for improving the adhesion of the composition. Preferred adhesion-imparting agents are organosilicon compounds having at least one alkoxy group bonded to a silicon atom in one molecule. This alkoxy group is exemplified by a methoxy group, an ethoxy group, a propoxy group, a butoxy group, and a methoxyethoxy group; and the methoxy group is particularly preferred. Moreover, non-alkoxy groups bonded to a silicon atom of this organosilicon compound are exemplified by substituted or non-substituted monovalent hydrocarbon groups such as alkyl groups, alkenyl groups, aryl groups, aralkyl groups, halogenated alkyl groups and the like; glycidoxyalkyl groups such as a 3-glycidoxypropyl group, a 4-glycidoxybutyl group, and the like; epoxy group-containing monovalent organic groups such as epoxycyclohexylalkyl groups (such as a 2-(3,4-epoxycyclohexyl)ethyl group, a 3-(3,4-epoxycyclohexyl)propyl group, and the like) and oxiranylalkyl groups (such as a 4-oxiranylbutyl group, an 8-oxiranyloctyl group, and the like); acrylic group-containing monovalent organic groups such as a 3-methacryloxypropyl group and the like; and a hydrogen atom. This organosilicon compound preferably has a silicon-bonded alkenyl group or silicon-bonded hydrogen atom. Moreover, due to the ability to impart good adhesion with respect to various types of substrates, this organosilicon compound preferably has at least one epoxy group-containing monovalent organic group in one molecule. This type of organosilicon compound is exemplified by organosilane compounds, organosiloxane oligomers and alkyl silicates. Molecular structure of the organosiloxane oligomer or alkyl silicate is exemplified by a linear structure, partially branched linear structure, branched chain structure, ring-shaped structure, and net-shaped structure. A linear chain structure, branched chain structure, and net-shaped structure are particularly preferred. This type of organosilicon compound is exemplified by silane compounds such as 3-glycidoxypropyltrimethoxysilane, 2-(3,4-epoxycyclohexyl)ethyltrimethoxysilane, 3-methacryloxy propyltrimethoxysilane, and the like; siloxane compounds having at least one of silicon-bonded alkenyl groups or silicon-bonded hydrogen atoms, and at least one silicon-bonded alkoxy group in one molecule; mixtures of a silane compound or siloxane compound having at least one silicon-bonded alkoxy group and a siloxane compound having at least one silicon-bonded hydroxyl group and at least one silicon-bonded alkenyl group in one molecule; and methyl polysilicate, ethyl polysilicate, and epoxy group-containing ethyl polysilicate.

In the present composition, the content of this adhesion-imparting agent is not particularly limited, but is preferably within the range of from 0.01 to 10 parts by weight per total of 100 parts by weight of the composition.

A reaction inhibitor, for example, an alkyne alcohol such as 2-methyl-3-butyn-2-ol, 3,5-dimethyl-1-hexyn-3-ol or 2-phenyl-3-butyn-2-ol; an ene-yne compound such as 3-methyl-3-penten-1-yne or 3,5-dimethyl-3-hexen-1-yne; or 1,3,5,7-tetramethyl-1,3,5,7-tetravinylcyclotetrasiloxane, 1,3,5,7-tetramethyl-1,3,5,7-tetrahexenylcyclotetrasiloxane or a benzotriazole may be incorporated as an optional component in the present composition.

In the present composition, the content of the reaction inhibitor is not limited, but is preferably from 0.0001 to 5 parts by weight per 100 parts by weight of the present composition.

In addition, the composition of the present invention may also contain one or more optical fine members selected from fluorescent microparticles, metal oxide microparticles, metal microparticles, nanocrystalline structures, and quantum dots as additional optional components. In addition, the composition may contain other metal oxide microparticles within a scope that does not deviate from the object of the present invention. It is preferable for some or all of these optical fine members to be surface-treated with the component (B). Similarly, as long as the object of the present invention is not inhibited, this composition may also contain inorganic powders such as fumed silica, sedimentary silica, molten silica, fumed titanium oxide, quartz powder, glass powder (glass beads), aluminum hydroxide, magnesium hydroxide, silicon nitride, aluminum nitride, boron nitride, silicon carbide, calcium silicate, magnesium silicate, diamond particles, and carbon nanotubes; or organic resin fine powders such as polymethacrylate resins, and it is preferable for some or all of these materials to be surface-treated with the component (B).

<Component (F): Fluorescent Material>

It is particularly preferable for the composition of the present invention to contain fluorescent microparticles. This fluorescent material is exemplified by substances widely used in light emitting diodes (LED), such as yellow, red, green, and blue light-emitting phosphors such as oxide type phosphors, oxynitride type phosphors, nitride type phosphors, sulfide type phosphors, oxysulfide type phosphors, and the like. Examples of oxide fluorescent substances include yttrium, aluminum, and garnet-type YAG green to yellow light-emitting fluorescent substances containing cerium ions, terbium, aluminum, and garnet-type TAG yellow light-emitting fluorescent substances containing cerium ions, and silicate green to yellow light-emitting fluorescent substances containing cerium or europium ions. Examples of oxynitride fluorescent substances include silicon, aluminum, oxygen, and nitrogen-type SiAlON red to green light-emitting fluorescent substances containing europium ions. Examples of nitride fluorescent substances include calcium, strontium, aluminum, silicon, and nitrogen-type cousin red light-emitting fluorescent substances containing europium ions. Examples of sulfide fluorescent substances include ZnS green light-emitting fluorescent substances containing copper ions or aluminum ions. Examples of oxysulfide fluorescent substances include Y2O2S red light-emitting fluorescent substances containing europium ions. These phosphors may be used as one type or as a mixture of two or more types.

In this composition, the content of the fluorescent microparticles is not particularly limited but is within the range of from 0.1 to 70 wt. % and is preferably within the range of from 1 to 20 wt. % in the composition.

As long as the object of the present invention is not inhibited, this composition may also contain additives such as antioxidants, denaturing agents, surfactants, dyes, pigments, anti-discoloration agents, ultraviolet absorbers, heat resistant agents, flame retardancy imparting agents, and solvents as other optional components.

The curing of this composition progresses at room temperature or while heating, but the composition is preferably heated in order to cure the composition quickly. The heating temperature is preferably from 50 to 200° C. Such a composition of the present invention may be used as an adhesive, a potting agent, a protective agent, a coating agent, or an underfill agent for electrical/electronic use. In particular, the composition is particularly suitable as an adhesive, a potting agent, a protective agent, a coating agent, or an underfill agent, in a semiconductor element for optical applications due to the high optical transmittance of the composition.

The cured product of the present invention will now be described in detail.

The cured product of the present invention is formed by curing the aforementioned curable silicone composition. The shape of the cured product of the present invention is not particularly limited, and examples include a sheet-shaped product and a film-shaped product. The cured product of the present invention can be handled alone or in a state in which it covers or seals an optical semiconductor element or the like.

The optical semiconductor device of the present invention will now be explained in detail.

This device is characterized in that an optical semiconductor element is covered or sealed by a cured product of the curable silicone composition described above. An example of this optical semiconductor element is a light emitting diode (LED) chip. Examples of such an optical semiconductor device include a light emitting diode (LED), a photocoupler, and a CCD.

An optical semiconductor device can be produced with the curable silicone composition described above by applying the composition to an appropriate thickness with a method such as casting, spin coating, or roll coating or covering an optical semiconductor element with by potting and then heating and drying at 50 to 200° C.

### EXAMPLES

The curable silicone composition, cured product, and optical semiconductor device of the present invention will be described in detail hereinafter using Practical Examples. In the compositions described below, Vi represents a vinyl group, Me represents a methyl group, Ph represents a phenyl group, and Np represents a naphthyl group. The refractive index was measured at 25° C. and 590 nm for liquid products and at 25° C. and 633 nm for cured products. The transmittance indicates the transmittance of light with a wavelength of 580 nm at a thickness of 10 μm. The end points of the reactions in the synthesis examples were confirmed by collecting part of the sample and confirming the consumption of reactive functional groups by infrared spectrophotometry (hereafter called “IR analysis”).

In the dispersion of the metal oxide microparticles, the definition of the average particle size is as follows.

### <Average Particle Size>

The average particle size of the metal oxide microparticles in the dispersion is the cumulant average particle size measured using a Zeta-potential and Particle Size Analyzer ELSZ-2 (manufactured by Otsuka Electronics Co., Ltd.).

### Synthesis Example 1

First, 450 g (125.5 millimoles) of a phenylmethylpolysiloxane capped at both terminals with vinyl dimethylsiloxane groups represented by the average structural formula: ViMe₂Si(OSiMePh)₂₅OSiMe₂Vi was mixed with a complex of platinum and 1,3-divinyltetramethyldisiloxane in an amount so that the platinum metal content was 2 ppm with respect to the total amount of the reaction mixture. After the mixture was heated to 90° C., 35.4 g (125.5 milliomoles) of a compound represented by the average structural formula: HMe₂SiOSiMe₂C₂H₄Si(OMe)₃ was dripped into the mixture. After the compound was stirred for 1 hour at 100° C., part of the compound was sampled. When IR analysis was performed, it was observed that the SiH groups had been completely consumed. The low-boiling point matter was removed by heating under reduced pressure, and 483 g of silethylene silicone (surface treatment agent No. 1) having the following average structure was obtained as a clear, colorless liquid (yield: 99.5%).

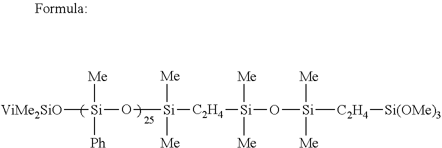

The refractive index was 1.5360.

### Synthesis Example 2

First, 193.2 g (708.9 milliomoles) of 1,1-diphenyl-1,3,3-trimethyldisiloxane and a complex catalyst consisting of platinum and 1,3-divinyltetramethyldisiloxane were added in an amount so that the platinum metal content was 2 ppm of the total amount of the reaction mixture in a nitrogen atmosphere. The mixture was heated to 80° C., and 200 g (779.8 millimoles) of trimethylsilyl undecylenate was dripped into the mixture at a temperature of from 85° C. to 88° C. After dripping was complete, the mixture was stirred for 1 hour at 100° C. When the mixture was sampled and analyzed by infrared spectroscopy, it was ascertained that the absorption of SiH groups had been eliminated and addition reactions had been completed. Next, 350 g of tetrahydrofuran and 68 g (3.8 moles) of water were added and stirred while heating for 2.5 hours at 60° C. to perform a desilylation reaction. After the mixture was cooled to room temperature, 150 g of toluene was added, and the mixture was left to stand for the purpose of phase separation. The aqueous phase was removed, and molecular sieves were added to the organic layer, which was then left to dry overnight. The molecular sieves were removed by filtering the organic layer, and the filtrate was removed by heating under reduced pressure to obtain 335.6 g (yield: 99.6%) of disiloxane (surface treatment agent No. 2) represented by the structural formula: Ph₂MeSiOSiMe₂C₁₀H₂₀COOH as the target product.

### Synthesis Example 3

First, 20 g (20.0 millimoles) of a phenylmethylpolysiloxane capped at both terminals with vinyl dimethylsiloxane groups represented by the average structural formula: ViMe₂Si(OSiMePh)₆OSiMe₂Vi was mixed with a complex of platinum and 1,3-divinyltetramethyldisiloxane in an amount so that the platinum metal content was 2 ppm with respect to the total amount of the reaction mixture. After the mixture was heated to 90° C., 3.9 g (10.0 millimoles) of a compound represented by the structural formula: HME₂SiOSiMe₂C₁₀H₂₀COOSiMe₃ was dripped into the mixture. After the mixture was stirred for 1 hour at 100° C., part of the mixture was sampled. When IR analysis was performed, it was observed that the SiH groups had been completely consumed. Next, 20 cc of tetrahydrofuran and 1.4 g of water were added and heat-refluxed for 3 hours to perform a desilylation reaction. The low-boiling point matter was removed by heating under reduced pressure, and as a result, 23.1 g (yield: 99.7%) of silethylene silicone (surface treatment agent No. 3) having the following average structure was obtained.

(Me₂ViSiO)_{1.5}(Me₂SiO(C₂H₄SiMe₂OSiMe₂C₁₀H₂₀COOH)_{0.5}(PhMeSiO)₆

<Example of Production of Barium Titanate Dispersion 1>

First, 9 g of barium titanate having a primary particle size of 20 nm, 1.8 g of the surface treatment agent No. 1, and 90 g of toluene were mixed in a beaker. The tip of an ultrasonic dispersion device (same as described above) with an output of 300 W was immersed in this mixture, and the beaker was cooled on ice and irradiated with ultrasonic waves for 90 minutes while ensuring that the liquid temperature did not exceed 40° C. After the beaker was left to stand for 24 hours, coarse particles were removed from the dispersion using decantation and a membrane filter with an airhole size of 0.2 μm to obtain a dispersion 1. When the resulting barium titanate was measured with a particle size measuring device using a dynamic light scattering method, the cumulant average particle size was 96.1 nm.

<Example of Production of Barium Titanate Dispersion 2>

Treatment agent No. 2 was added to an isopropoxyethanol dispersion of barium titanate with a cumulant particle size of 22.8 nm synthesized by a sol gel method so that the weight ratio of barium titanate and treatment agent No. 16 was 1:0.3. After the low-boiling point matter was removed by heating under reduced pressure, toluene was added in an amount 9 times the weight of the residual amount so as to prepare a 10 wt. % toluene dispersion (dispersion 2). The measured cumulant particle size was 33.7 nm.

<Example of Production of Barium Titanate Dispersion 3>

First, 36 g of barium titanate with a primary particle size of 20 nm, 20 g of surface treatment agent No. 1, and 360 g of toluene were mixed and stirred using a bead mill filled with 30 μm beads to obtain dispersion 3. When the resulting barium titanate was measured with a particle size measuring device using a dynamic light scattering method, the cumulant average particle size was 97 nm. (Transformation rate: 100%)

<Example of Production of Titanium Oxide Dispersion>

First, 6 g of titanium oxide with a primary particle size of 35 nm, 1.8 g of surface treatment agent No. 1 described above, and 90 g of toluene were mixed in a beaker. The tip of an ultrasonic dispersion device (same as described above) with an output of 300 W was immersed in this mixture, and the beaker was cooled on ice and irradiated with ultrasonic waves for 90 minutes while ensuring that the liquid temperature did not exceed 40° C. After the beaker was left to stand for 24 hours, coarse particles were removed from the dispersion using decantation and a membrane filter with an airhole size of 0.2 μm to obtain a dispersion 4. When the resulting titanium oxide dispersion was measured with a particle size measuring device using a dynamic light scattering method, the cumulant average particle size was 138.0 nm.

### Practical Examples 1 to 3

### Evaluation of the Curable Organopolysiloxane Composition and the Cured Product

With the compositions illustrated in Table 1, the aforementioned dispersion 1 of barium titanate in an amount so that the barium titanate content was a prescribed amount, a vinyl functional polyorganosiloxane, and an SiH functional polyorganosiloxane were mixed. Next, a 1,3-divinyltetramethyl disiloxane platinum complex was mixed at an amount in which the platinum metal was 2 ppm with respect to the solid content in weight units so as to prepare a solution of a curable organopolysiloxane composition.

This solution of the curable organopolysiloxane was dripped onto a glass plate and dried for one hour at 70° C. After the solvent was removed, the mixture was heated for 2 hours at 150° C. to obtain a cured product.

The makeup of the cured organopolysiloxane compositions and the evaluation results of the cured products are shown in Table 1. The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition.

### <Refractive Index of the Cured Product>

The refractive index of the cured product of the curable silicone composition formed with the method described above was measured using a prism coupler method at room temperature. A 632.8 nm (approximately 633 nm) laser light source was used for measurements.

### <Transmittance of Cured Product>

The transmittance of the cured product indicates the transmittance of light with a wavelength of 580 nm at a thickness of 10 μm.

In addition, the appearance and strength of each cured product was evaluated in accordance with the criteria shown below.

“Appearance”: The presence or absence of cracking (cracks) in the cured product was evaluated visually.
“Strength”: The presence or absence of tack was evaluated by touching the surface of the cured product with a finger.

### <Heat Resistance of the Cured Product>

The cured product was heated for 24 hours at 220° C., and the heat resistance was evaluated from the degree of discoloration.

TABLE 1

| | | | Practical | | |
|---|---|---|---|---|---|
| | | | Examples | | |
| | | | 1 | 2 | 3 |
| Composition | (ViMe₂SiO_{1/2})₂₅(PhSiO_{3/2})₇₅ | | — | — | 23.5 |
| % by mass | (ViPhMeSiO_{1/2})₄₀(NpSiO_{3/2})₆₀ | | 22 | 28 | — |
| (Solid content conversion excluding | HMe₂SiO(Ph₂SiO)SiMe₂H | | — | 12 | — |
| toluene) | HMe₂SiO(Ph₂SiO)_{2.5}SiMe₂H | | 18 | — | 16.5 |
| | Surface treatment agent | | 10 | 10 | 10 |
| | No. 1 | | | | |
| | Barium titanate | | 50 | 50 | 50 |
| SiH/Vi ratio | | | 1.0 | 1.0 | 1.0 |
| Characteristics of the cured product | Refractive index (633 nm) | | 1.680 | 1.691 | 1.667 |
| | Appearance/ | Cracks | No | No | No |
| | strength | Tack | No | No | No |

| | | | |
|---|---|---|---|
| Transmittance (%) | 89 | 91 | 82 |

| | |
|---|---|
| Heat resistance | Very slight yellowing |

### Comparative Examples 1 and 2

### Evaluation of the Curable Organopolysiloxane Composition and the Cured Product

With the compositions illustrated in Table 2, the titanium oxide dispersion 2 described above in an amount so that the titanium oxide content was a prescribed amount, a vinyl functional polyorganosiloxane, and an SiH functional polyorganosiloxane were mixed. Next, a 1,3-divinyltetramethyl disiloxane platinum complex was mixed at an amount in which the platinum metal was 2 ppm with respect to the solid content in weight units so as to prepare a solution of a curable organopolysiloxane composition.

This solution of the curable organopolysiloxane composition was dripped onto a glass plate and dried for one hour at 70° C. After the solvent was removed, the mixture was heated for 2 hours at 150° C. to obtain a cured product.

The makeup of the cured organopolysiloxane compositions and the evaluation results of the cured products are shown in Table 2. The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition.

The evaluation criteria for each characteristic are the same as in Practical Examples 1 to 3.

TABLE 2

| | | | Comparative | |
|---|---|---|---|---|
| | | | Examples | |
| | | | 1 | 2 |
| Composition | (ViMe₂SiO_{1/2})₂₅(PhSiO_{3/2})₇₅ | | — | 33.7 |
| % by mass | (ViPhMeSiO_{1/2})₄₀(NpSiO_{3/2})₆₀ | | 31.2 | — |
| (Solid content | HMe₂SiO(Ph₂SiO)SiMe₂H | | 25.5 | 23 |
| conversion | Surface treatment agent No. 1 | | 10 | 10 |
| excluding toluene) | Titanium oxide | | 33.3 | 33.3 |
| SiH/Vi ratio | | | 1.0 | 1.0 |
| Characteristics | Refractive index (633 nm) | | 1.688 | 1.680 |
| of the cured | Appearance/ | Cracks | No | No |
| product | strength | Tack | No | No |

| | | |
|---|---|---|
| Transmittance (%) | 67 | 52 |

| | |
|---|---|
| Heat resistance | Clear |
| | discoloration |

### Comparative Example 3

### Evaluation of the Curable Organopolysiloxane Composition and the Cured Product

A zirconium oxide dispersion (OZ-S30K manufactured by Nissan Chemical Industries, methyl ethyl ketone solution containing 30% zirconium oxide) and surface treatment agent No. 1 were mixed with the compositions shown in Table 3. Next, a vinyl functional polyorganosiloxane and an SiH functional polyorganosiloxane were mixed. Next, a 1,3-divinyltetramethyl disiloxane platinum complex was mixed at an amount in which the platinum metal was 2 ppm with respect to the solid content in weight units so as to prepare a solution of a curable polymer composition. A solution of curable organopolysiloxane composition was prepared.

This solution of the curable organopolysiloxane composition was dripped onto a glass plate and dried for one hour at 70° C. After the solvent was removed, the mixture was heated for 2 hours at 150° C. to obtain a cured product.

The makeup of the cured organopolysiloxane compositions and the evaluation results of the cured products are shown in Table 3. The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition.

The evaluation criteria for each characteristic are the same as in Practical Examples 1 to 3.

TABLE 3

| | | | Comparative |
|---|---|---|---|
| | | | Example |
| | | | 3 |
| Composition | (ViPhMeSiO_{1/2})₄₀(NpSiO_{3/2})₆₀ | | 22 |
| % by mass | HMe₂SiO(Ph₂SiO)SiMe₂H | | 18 |
| (excluding methyl | Surface treatment agent No. 1 | | 10 |
| ethyl ketone) | Zirconium oxide | | 50 |
| | *“OZ-S30K” manufactured | | |
| | by Nissan Chemical Industries | | |
| SiH/Vi ratio | | | 1.0 |
| Characteristics of the | Refractive index (633 nm) | | 1.637 |
| cured product | Appearance/ | Cracks | No |
| | strength | Tack | No |

| | |
|---|---|
| Heat resistance | Very |
| | slight |
| | yellowing |

When Practical Example 1 and Comparative Example 3 are compared, there is a difference of 0.043 between the refractive indices, so it can be seen that the refractive index of the cured product is clearly higher when barium titanate is used than when zirconium oxide is used.

### Practical Example 4

The respective components were mixed with the compositions shown in Table 4. Further, a solution of a curable organopolysiloxane composition was prepared by mixing a platinum 1,3-divinyltetramethyldisiloxane complex in an amount so that the platinum metal was 6.6 ppm in weight units with respect to the solid content, and after the solution was poured onto a plate made of Teflon (registered trademark), the solution was left to stand overnight at room temperature.

This solution of the curable organopolysiloxane was dripped onto a glass plate and heated for one hour at 170° C. to obtain a cured product.

The compositions in the table are expressed as the mass % of the curable composition (solid content) excluding the toluene and methyl ethyl ketone in each dispersion.

The makeup of the cured organopolysiloxane compositions and the evaluation results of the cured products are shown in Table 4.

The SiH/Vi ratio in the table represents the number of moles of silicon-bonded hydrogen atoms in the SiH functional polyorganosiloxane with respect to a total of 1 mole of the dispersion and vinyl groups in the vinyl functional polyorganosiloxane in the curable organopolysiloxane composition. The evaluation criteria for each characteristic are the same as in Examples 1 to 3.

TABLE 4
Practical Example 4

| Composition | Dispersion 2 (solid content conversion | | 39.2 |
|---|---|---|---|
| % by mass | excluding the solvent) | | |
| | Benzoic acid | | 3.1 |
| | Surface treatment agent No. 3 | | 6.9 |
| | Polyphenylmethylsiloxane capped at both | | 31.2 |
| | terminals with PhMeViSiO groups having | | |
| | an average degree of polymerization of 6 | | |
| | Polyphenylmethylsiloxane capped at both | | 15.3 |
| | terminals with Me₂HSiO groups having an | | |
| | average degree of polymerization of 6 | | |
| | Polysiloxane represented by the average | | 4.3 |
| | structural formula (Me₂HSiO)₆(PhSiO)₄ | | |
| SiH/Vi ratio | | | 1.0 |
| BaTiO₃ (mass %) | | | 30 |
| Characteristics | Refractive index (633 nm) | | 1.579 |
| of the cured | Appearance/strength | Cracks | No |
| product | | Tack | No |

### Practical Examples 5 to 7

A 68.7 weight % toluene solution of polysiloxane represented by the average formula (PhSiO)_{0.41}(PhMeSiO)_{0.59}, dispersion 2, and zinc octanoate (in an amount so that the weight of zinc was 2000 ppm with respect to the solid content) were mixed in tetrahydrofuran, and the low-boiling point matter was partially removed while heating under reduced pressure to obtain a dispersion with a solid concentration of approximately 20 wt. %. After these mixtures were poured onto a plate made of Teflon (registered trademark), they were left to stand overnight at room temperature and heated for 2 hours in an oven at 50° C. Next, the mixtures were heated for 2 hours under reduced pressure at the same temperature, returned to atmospheric pressure, and then cured by heating for 1 hour at 170° C. All of the cured products were clear, and the values of the film thickness, transmittance, and refractive index of the cured products are shown in the following Table 5.

TABLE 5

| | Practical | Practical | Practical |
|---|---|---|---|
| | Example 5 | Example 6 | Example 7 |
| Weight ratio of solid content in | 0.54/1 | 0.93/1 | 1.56/1 |
| (PhSiO)_{0.41}(PhMeSiO)_{0.59}/dispersion | | | |
| 2 | | | |
| Refractive index (633 nm) | 1.634 | 1.611 | 1.595 |
| Transmittance (580 nm) | 87.1% | 88.5% | 88.0% |
| Film thickness (mm) | 0.16 | 0.22 | 0.31 |

### Practical Examples 8 to 10

Using the barium titanate dispersion 3 obtained in Production Example 3, the solutions were mixed with the compositions shown in the following Table 6, and a complex catalyst consisting of platinum and 1,3-divinyltetramethyldisiloxane was further added so that the platinum metal concentration was 6.6 ppm of the solid content. The mixture was heated for 2 hours at 150° C. to obtain a curable silicone composition.

TABLE 6

| | | Practical | Practical | Practical |
|---|---|---|---|---|
| | | Example 8 | Example 9 | Example 10 |
| Composition | (ViMe₂SiO_{1/2})₂₅(PhSiO_{3/2})₇₅ | 19.4 | 13.3 | 7.3 |
| % by mass | ViMe₂SiO(PhMeSiO)₂₀SiMe₂Vi | 24.0 | 17.0 | 10.0 |
| | HMe₂SiO(Ph₂SiO)SiMe₂H | 10.0 | 7.5 | 5.0 |
| | Barium titanate dispersion 3 | 46.7 | 62.2 | 77.8 |
| | obtained in Production | | | |
| | Example 3 (excluding the | | | |
| | solvent) | | | |
| SiH/Vi ratio | | 1.0 | 1.0 | 1.0 |
| BaTiO₃ (mass %) | | 30 | 40 | 50 |
| Characteristics | Refractive index (633 nm) | 1.600 | 1.616 | 1.642 |
| of the cured | | | | |
| product | | | | |

### Preparation Example 1 of a Silica-Covered Barium Titanate Powder

Ten g of barium titanate having a cumulant average particle size of 35 nm was placed in 170 g of water, and 5.2 g (50.9 millimoles) of concentrated hydrochloric acid was added. Next, barium titanate was dispersed in the hydrochloric acid aqueous solution using an ultrasonic dispersion device. Next, a sodium silicate aqueous solution obtained by dissolving 1.3 g (3.6 millimoles) of sodium silicate represented by the average structural formula: Na₂O_{2.2}SiO₂ 9.3 H₂O in 5 g of water while irradiating the solution with ultrasonic waves was gradually dripped into the mixture. Further, a sodium hydroxide aqueous solution obtained by dissolving 1.75 g (43.7 millimoles) of sodium hydroxide in 5 g of water was gradually dripped into the mixture. After it was confirmed that the pH was neutral, the precipitated solid was removed by filtration and washed with water twice. The water content was removed by heating under reduced pressure at 80° C. to obtain 9.2 g of a silica-covered barium titanate powder. The weight ratio of the silica component and the barium titanate was calculated from the loaded weight to be 0.047/1.

### Preparation Example 2 of a Silica-Covered Barium Titanate Powder

A silica-covered barium titanate powder was obtained in the same manner as in Practical Example 11 with the exception of using 2.6 g (7.2 millimoles) of sodium silicate and 1.4 g (36.5 millimoles) of sodium hydroxide. The weight ratio of the silica component and the barium titanate was calculated from the loaded weight to be 0.096/1.

<Preparation Example of a Silica-Coated Barium Titanate Dispersion Using a Bead Mill>

A silica-covered barium titanate dispersion treated with surface treatment agent No. 1 can be obtained by mixing 36 g of the silica-covered barium titanate powder obtained in preparation example 1 of a silica-covered barium titanate powder, 20 g of surface treatment agent No. 1, and 360 g of toluene and stirring the mixture using a bead mill filled with 30 μm beads.

<Preparation Example of a Curable Silicone Composition Using Silica-Covered Barium Titanate>

A curable silicone composition having a high refractive index of at least 1.55 can be obtained by mixing the silica-covered barium titanate dispersion obtained above with a condensation-reactive or hydrosilylation-reactive organosilicon compound and curing the mixture. These silicone compositions are suitable as optical materials, particularly as sealants or chip coating materials for optical semiconductor elements.

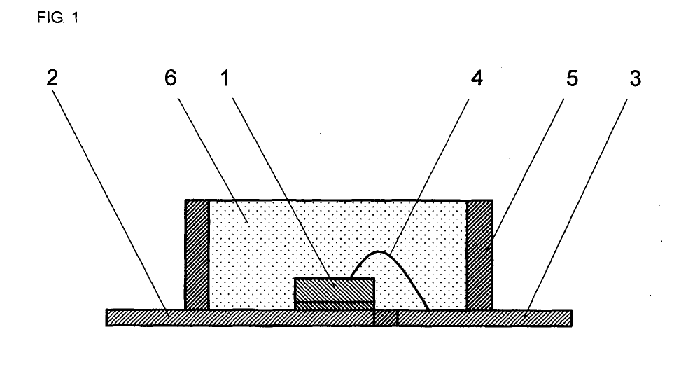

The curable silicon composition of the present invention is suitable as a sealing agent or a chip coating material for an optical semiconductor element. For example, a cross-sectional view of a surface-mounted LED is illustrated in FIG. 1 as an example of an optical semiconductor element using the surface treatment agent for an optical material according to the present invention.

In the LED illustrated in FIG. 1, an optical semiconductor element 1 is die-bonded to a lead frame 2, and the semiconductor element 1 and a lead frame 3 are wire-bonded by a bonding wire 4. This optical semiconductor element 1 is resin-sealed by a silicone cured product formed by the curable silicon composition of the present invention. The silicone cured product of the present invention has a refractive index of at least 1.55, so the light-extraction efficiency improves.

### EXPLANATION OF SYMBOLS

1 light-emitting element
2 lead frame
3 lead frame
4 bonding wire
5 frame material
6 cured product of the curable silicon composition of the present invention

1. A curable silicone composition comprising: (A) barium titanate microparticles or barium titanate microparticles having a surface which is partially or entirely covered by a silica layer with a cumulant average particle size of at most 200 nm, a refractive index after curing being at least 1.55.

2. The curable silicone composition according to claim 1, further comprising: (B) an organosilicon compound having a functional group selected from a highly polar functional group, a hydroxyl group-containing group, a silicon atom-containing hydrolyzable group, or metal salt derivatives thereof bonded to silicon atoms directly or via a functional group with a valency of (n+1), where n is a number equal to 1 or greater and
having at least one structure in the molecule in which the silicon atoms are bonded to any siloxane unit represented by R¹SiO_{1/2}, R¹₂SiO_{2/2}, R¹SiO_{3/2}, and SiO_{4/2}, wherein R¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1).

3. The curable silicone composition according to claim 2, wherein the component (A) comprises barium titanate microparticles or barium titanate microparticles having a surface which is partially or entirely covered by a silica layer surface-treated by the component (B), the curable silicone composition being hydrosilylation reaction curable.

4. The curable silicone composition according to claim 2, comprising:
(A) barium titanate microparticles or barium titanate microparticles having a surface which is partially or entirely covered by a silica layer with a cumulant average particle size of at most 200 nm;
(B) an organosilicon compound having a functional group selected from a highly polar functional group, a hydroxyl group-containing group, a silicon atom-containing hydrolyzable group, or metal salt derivatives thereof bonded to silicon atoms directly or via a functional group with a valency of (n+1), n is a number equal to 1 or greater, and having at least one structure in the molecule in which the silicon atoms are bonded to any siloxane unit represented by R³¹₃SiO_{1/2}, R³¹₂SiO_{2/2}, R³¹SiO_{3/2}, and SiO_{4/2}, wherein R³¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1);
(C) an organopolysiloxane having at least two alkenyl groups in each molecule;
(D) an organopolysiloxane having at least two silicon-bonded hydrogen atoms in each molecule; and
(E) a hydrosilylation reaction catalyst.

5. The curable silicone composition according to claim 4, wherein part or all of the component (C) or the component (D) is an organopolysiloxane represented by the average unit formula:
(R²¹₃SiO_{1/2})ₐ(R²¹₂SiO_{2/2})_{b}(R²²SiO_{3/2})_{c}(SiO_{4/2})_{d}
wherein the R²¹ moieties are alkyl groups, alkenyl groups, phenyl groups, or hydrogen atoms; the R²² moieties are groups recited for the R²¹ moieties, condensed polyaromatic groups, or groups including a condensed polyaromatic group, provided that at least two of the R²¹ or R²² moieties in the molecule are alkenyl groups or hydrogen atoms and at least one R²² moiety in the molecule is a condensed polyaromatic group or a group including a condensed polyaromatic group; and a, b, c, and d are numbers satisfying the formulae: 0.01≦a≦0.8, 0≦b≦0.5, 0.2≦c≦0.9, 0≦d<0.2, and a+b+c+d=1.

6. The curable silicone composition according to claim 2, wherein the component (B) is an organosilicon compound having an alkenyl group or a silicon-bonded hydrogen atom in the molecule; and
a silicon-bonded hydrolyzable group or hydroxyl group bonded to silicon atoms directly or via a functional group with a valency of (n+1), where n is a number equal to 1 or greater.

7. The curable silicone composition according to claim 1, further comprising (F) a fluorescent material.

8. A cured product produced by curing the curable silicone composition according to claim 1.

9. A semiconductor sealing material comprising the curable silicone composition according to claim 1.

10. An optical semiconductor device formed by covering or sealing an optical semiconductor element with the curable silicone composition according to claim 1.

11. The curable silicone composition according to claim 3, comprising:
(A) barium titanate microparticles or barium titanate microparticles having a surface which is partially or entirely covered by a silica layer with a cumulant average particle size of at most 200 nm;
(B) an organosilicon compound having a functional group selected from a highly polar functional group, a hydroxyl group-containing group, a silicon atom-containing hydrolyzable group, or metal salt derivatives thereof bonded to silicon atoms directly or via a functional group with a valency of (n+1), n is a number equal to 1 or greater, and
having at least one structure in the molecule in which the silicon atoms are bonded to any siloxane unit represented by R³¹₃SiO_{1/2}, R³¹₂SiO_{2/2}, R³¹SiO_{3/2}, and SiO_{4/2}, wherein R³¹ is a substituted or unsubstituted monovalent hydrocarbon group, a hydrogen atom, a halogen atom, a hydroxyl group, an alkoxy group, or a functional group selected from a highly polar functional group, a hydroxyl group-containing group, a silicon atom-containing hydrolyzable group, or metal salt derivatives thereof bonded to silicon atoms via a functional group with a valency of (n+1);
(C) an organopolysiloxane having at least two alkenyl groups in each molecule;
(D) an organopolysiloxane having at least two silicon-bonded hydrogen atoms in each molecule; and
(E) a hydrosilylation reaction catalyst.

12. The curable silicone composition according to claim 11, wherein part or all of the component (C) or the component (D) is an organopolysiloxane represented by the average unit formula:
(R²¹₃SiO_{1/2})ₐ(R²¹₂SiO_{2/2})_{b}(R²²SiO_{3/2})_{c}(SiO_{4/2})_{d}
wherein the R²¹ moieties are alkyl groups, alkenyl groups, phenyl groups, or hydrogen atoms; the R²² moieties are groups recited for the R²¹ moieties, condensed polyaromatic groups, or groups including a condensed polyaromatic group, provided that at least two of the R²¹ or R²² moieties in the molecule are alkenyl groups or hydrogen atoms and at least one R²² moiety in the molecule is a condensed polyaromatic group or a group including a condensed polyaromatic group; and a, b, c, and d are numbers satisfying the formulae: 0.01≦a≦0.8, 0≦b≦0.5, 0.2≦c≦0.9, 0≦d<0.2, and a+b+c+d=1.
